(19) United States
(12) Patent Application Publication
(10) Pub. No.: US 2025/0251663 A1
(43) Pub. Date: Aug. 7, 2025

(54) PHOTOSENSITIVE RESIN COMPOSITION, PRODUCTION METHOD FOR POLYIMIDE CURED FILM USING SAME, AND POLYIMIDE CURED FILM

(71) Applicant: ASAHI KASEI KABUSHIKI KAISHA, Tokyo (JP)

(72) Inventors: Satoshi SHIBUI, Tokyo (JP); Shinichiro ISHIDA, Tokyo (JP); Yuka SATO, Tokyo (JP); Takanobu FUJIOKA, Tokyo (JP)

(73) Assignee: ASAHI KASEI KABUSHIKI KAISHA, Tokyo (JP)

(21) Appl. No.: 18/856,246

(22) PCT Filed: Mar. 30, 2023
(86) PCT No.: PCT/JP2023/013275

§ 371 Date: Oct. 11, 2024

(30) Foreign Application Priority Data
May 23, 2022 (JP) 2022-083841

(51) Int. Cl. G03F 7/037; C08G 73/10; C08G 73/12; G03F 7/029; G03F 7/031; G03F 7/075; G03F 7/16; G03F 7/20

(52) U.S. Cl. CPC G03F 7/037; C08G 73/1032; C08G 73/1067; C08G 73/126; G03F 7/029; G03F 7/031; G03F 7/075; G03F 7/165; G03F 7/168; G03F 7/2012

(57) ABSTRACT

According to the present disclosure, there are provided: a photosensitive resin composition which has low dielectric properties, low cure shrinkage, good storage stability, and reduced phase separation during coating, and with which a cured relief pattern having high resolution and high copper adhesion can be formed; a method for producing a polyimide cured film using said composition; and a polyimide cured film. The photosensitive resin composition of the present disclosure includes 100 parts by weight of a copolymer resin containing a polyimide and polyimide precursor, 0.5-30 parts by weight of a photopolymerization initiator, and 100-1000 parts by weight of a solvent. The copolymer resin has a polyimide block portion and a polyimide precursor block portion with a specific structure, and the copolymer resin composed of the polymide and the polyimide precursor satisfies the formula

0.10<n₂/(n₂+n₃)<0.90

### TECHNICAL FIELD

The present disclosure relates to a photosensitive resin composition, and a method for producing a polyimide cured film and a polyimide cured film using the same.

### BACKGROUND ART

There have conventionally been used, as insulating materials for electronic components, passivation films, surface protective films and interlayer insulating films for semiconductor devices, polyimide resins, polybenzoxazole resins and phenolic resins which have excellent heat resistance, electrical properties and mechanical properties. Of these resins, those provided in the form of a photosensitive resin composition can easily form a heat-resistant relief pattern film by application, exposure, development and ring closure treatment (imidization, benzoxazolization) and thermal crosslinking due to curing of the composition. Such a photosensitive resin composition has characteristics of enabling significant reduction in the process compared to conventional non-photosensitive materials, and is therefore used in the fabrication of semiconductor devices.

Incidentally, semiconductor devices (hereinafter also referred to as “elements”) are mounted on printed circuit boards in various manners depending on the purposes. A conventional element was generally fabricated by a wire bonding method in which a fine wire is used to connect an external terminal (pad) of the element to a lead frame. However, today, the speed of devices has increased and the operating frequency has reached up to GHz, a difference in wiring length of each terminal in mounting has come to affect the operation of devices. Therefore, mounting of elements for high-end applications requires precise control of the mounting wiring length, and thus wire bonding is no longer sufficient to meet these requirements.

Therefore, there has been proposed flip-chip mounting in which a rewiring layer is formed on the surface of a semiconductor chip and, after forming bumps (electrodes) thereon, the chip is flipped over and the chip is directly mounted on a printed circuit board. Since this flip-chip mounting can accurately control the wiring distance, it has been adopted for high-end devices which handle high-speed signals, or mobile phones due to its small mounting size, and demand is growing rapidly. More recently, there has been proposed a semiconductor chip mounting technique called fan-out wafer level package (FOWLP) in which a pre-processed wafer is diced to produce individual chips and the individual chips are reconstructed on a support, and after sealing with a mold resin, a rewiring layer is formed after stripping the support (for example, PTL 1). In the fan-out wafer level package, since the rewiring layer is formed at a small thickness, the height of the package can be reduced, and there are advantages such as high-speed transmission and cost reduction.

In recent years, significant increase in volume of information communication has necessitated a shift to 5th generation (5G) communication using a frequency of 3 GHz or more, or to ultra-high frequency bands from quasi-millimeter wave bands (20 GHz to 30 GHz) to millimeter wave bands (30 GHz or more) where a wider frequency bandwidth can be easily secured, thus requiring high-frequency compatibility not only in the printed circuit boards but also in the semiconductor chips on which the boards are mounted. To reduce transmission loss, there has been developed an antenna-in-package (AiP) in which a front-end module (FEM) which transmits and receives radio waves, and an antenna are integrated (see, for example, PTL 2 below). The short wiring length of the AiP makes it possible to suppress the transmission loss which increases in proportion to the wiring length. However, as the communication frequency band increases, there is a demand for rewiring materials with low dielectric properties. Further, since AiP requires multiple rewiring layers, as in the conventional FOWLP, the rewiring layer must also be planarized.

As a means for solving the problems, there are roughly two conceivable methods of reducing the transmission loss in a high frequency band, a method of reducing dielectric loss and a method of reducing conductor loss. As for the former, the photosensitive resin composition is required to have low dielectric properties (low dielectric loss tangent, low dielectric constant), and examples thereof include PTL 3, PTL 4 and PTL 5. However, in PTL 3, the measurement frequency is as low as 1 GHz, and therefore it is insufficient as the rewiring layer for AiP, which is used at high frequencies. In PTL 4, since a polyimide precursor resin and a polyimide resin are blended, there are concerns about the storage stability of the photosensitive resin composition and phase separation during coating. In PTL 5, a varnish containing a polyimide precursor resin is heat-aged to fabricate a partially imidized polyimide precursor in the varnish. However, since it is difficult to control the imidization rate, there is a problem with uniformity during spin coating, and it is difficult to achieve high resolution.

As a means for planarizing the rewiring layer, a method of suppressing the cure shrinkage of the rewiring layer is considered, and PTL 6 is given as an example. In PTL 6, high flatness is achieved by using a polyfunctional (meth)acrylate in a polyimide resin. However, there is no description about the dielectric properties, and there is concern that the dielectric properties may deteriorate at high frequency due to the influence of a large amount of polyfunctional (meth)acrylate.

### CITATION LIST

### Patent Literature

[PTL 1] JP 2005-167191 A
[PTL 2] US 2016/0,104,940 A
[PTL 3] WO 2019/044874 A
[PTL 4] TW 2020/026762 A
[PTL 5] JP 2022-54416 A
[PTL 6] JP 2021-152634 A

### SUMMARY

### Technical Problem

In recent years, due to the diversification of package mounting technology, the types of supports have diversified and rewiring layers has been multi-layered, and thus the dielectric constant and dielectric loss tangent (tanδ) of the insulating material used for wiring formation have a significant impact. When the dielectric constant and dielectric loss tangent are high, the transmission loss increases due to an increase in dielectric loss. While a polyimide resin has high material reliability due to its excellent insulation performance and thermo-mechanical properties, high dielectric constant and dielectric loss tangent are problematic due to the polar functional groups derived from an imide group, polar functional groups to be added for photosensitization, and additives. The planarity of the rewiring layer derived from low cure shrinkage due to multi-layering of rewiring layers may be sometimes problematic.

An object of the present disclosure is to provide a photosensitive resin composition which has low dielectric properties, low cure shrinkage and satisfactory storage stability, and exhibits reduced phase separation during coating, and is capable of forming a cured relief pattern with high resolution and high copper adhesion, and a method for producing a polyimide cured film and a polyimide cured film using the same.

### Solution to Problem

Examples of the embodiment of the present disclosure are listed in items [1] to [16] below.

[1]

A photosensitive resin composition comprising:
(A) 100 parts by weight of a copolymer resin containing a polyimide and polyimide precursor;
(B) 0.5 to 30 parts by weight of a photopolymerization initiator; and
(C) 100 to 1,000 parts by weight of a solvent;

wherein the copolymer resin containing the polyimide and polyimide precursor comprises a structure represented by the following general formula (1):

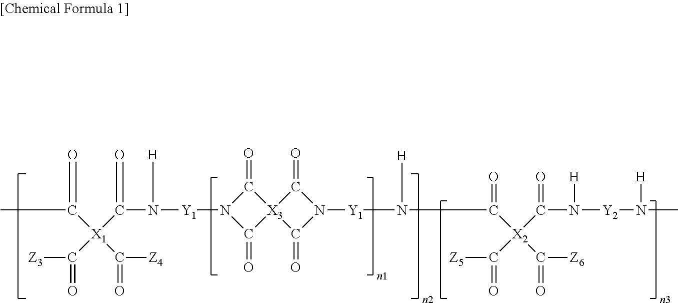

wherein, in formula (1), X₁, X₂ and X₃ are each independently a tetravalent organic group having 6 to 40 carbon atoms, Y₁ and Y₂ are each independently a divalent organic group having 6 to 40 carbon atoms, n₁ is an integer of 2 to 30, n₂ and n₃ are each independently an integer of 2 to 150, Z₃, Z₄, Z₅ and Z₆ are each independently a monovalent organic group, and at least one of Z₃, Z₄, Z₅ and Z₆ is a photopolymerizable functional group, and

the copolymer resin containing the polyimide and polyimide precursor satisfies 0.10<n₂/(n₂+n₃)<0.90.

[2]

The photosensitive resin composition according to item 1, wherein the photopolymerizable functional group includes a structure represented by the following general formula (2):

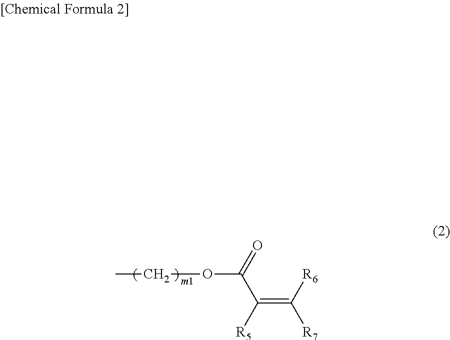

wherein, in formula (2), R₅, R₆ and R₇ are each independently a hydrogen atom or a monovalent organic group having 1 to 3 carbon atoms, and m₁ is an integer of 2 to 10.
[3]

The photosensitive resin composition according to item 1 or 2, wherein n₂/(n₂+n₃) satisfies 0.40<n₂/(n₂+n₃)<0.90.

[4]

The photosensitive resin composition according to any one of items 1 to 3, wherein the copolymer resin containing the polyimide and polyimide precursor (A) does not contain a halogen atom.

[5]

The photosensitive resin composition according to any one of items 1 to 4, wherein, in polyimide of a polyimide cured film obtained by heating and curing the photosensitive resin composition at 350° C., the imide group concentration U, which is the ratio of the molecular weight of imide groups to the molecular weight of repeating units including structures derived from tetracarboxylic dianhydride and diamine, is 12% by weight to 26% by weight.

[6]

The photosensitive resin composition according to any one of items 1 to 5, wherein X₁, X₂ and X₃ of the copolymer resin containing the polyimide and polyimide precursor (A) include a structure represented by the following general formula (4):

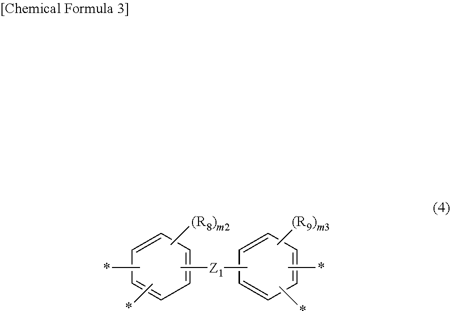

wherein, in formula (4), R₈ and R₉ are each independently an organic group having 1 to 10 carbon atoms, m₂ and m₃ are an integer selected from 0 to 4 and satisfy m₂+m₃≥1, Z₁ is selected from the group consisting of a single bond, an organic group having 1 to 30 carbon atoms and an organic group containing a heteroatom, two of * mean bonding to the main chain of the resin, and the other two mean bonding to the side chain in the above general formula (1); and/or,

Y₁ and/or Y₂ include(s) a structure represented by the following general formula (7):

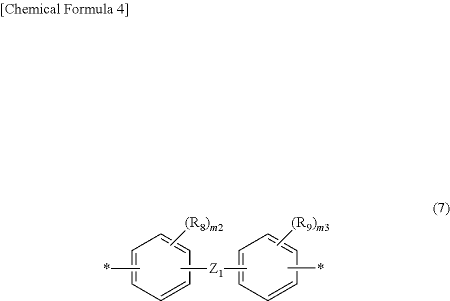

wherein, in formula (7), R₈ and R₉ are each independently an organic group having 1 to 10 carbon atoms, m₂ and m₃ are an integer selected from 0 to 4 and satisfy m₂+m₃≥1, Z₁ is selected from the group consisting of a single bond, an organic group having 1 to 30 carbon atoms and an organic group containing a heteroatom, and * means bonding to the main chain of the resin.
[17]

The photosensitive resin composition according to any one of items 1 to 6, wherein the copolymer resin containing the polyimide and polyimide precursor (A) has the other reactive substituents which are polymerized by heat or light at the resin end, and are different from the photopolymerizable functional groups included in the repeating units.

[8]

The photosensitive resin composition according to any one of items 1 to 7, further comprising (D) a silane coupling agent.

[9]

The photosensitive resin composition according to any one of items 1 to 8, further comprising (E) a radically polymerizable compound.

[10]

The photosensitive resin composition according to any one of items 1 to 9, further comprising (F) a thermal crosslinking agent.

[11]

The photosensitive resin composition according to any one of items 1 to 10, further comprising (G) a filler.

[12]

A method for producing a polyimide cured film, the method comprising the following steps (1) to (5):
(1) a step of applying the photosensitive resin composition according to any one of items 1 to 11 on a substrate to form a photosensitive resin layer on the substrate;
(2) a step of heating and drying the photosensitive resin layer thus obtained; (3) a step of exposing the heat-dried photosensitive resin layer;
(4) a step of developing the exposed photosensitive resin layer; and
(5) a step of heat-treating the developed photosensitive resin layer to form a polyimide cured film.
   [13]

A method for producing a polyimide cured film, the method comprising applying the resin composition according to any one of items 1 to 11 on a substrate, and subjecting the substrate to an exposure treatment, a development treatment and then a heat treatment, wherein the cured film has a dielectric loss tangent of 0.003 to 0.011 as measured at 40 GHz by the perturbation type split cylinder resonator method.

[14]

A polyimide cured film which has a dielectric loss tangent of 0.003 to 0.011 as measured at a frequency of 40 GHz by the perturbation type split cylinder resonator method, and has RFA of 0.81 to 0.93, and satisfies the following formula:

$$85 < RFA / tan {δ}_{40} < 175$$

wherein RFA represents a residual film ratio after heat curing (ratio), and tanδ₄₀ represents the dielectric loss tangent as measured at a frequency of 40 GHz by the perturbation type split cylinder resonator method.
[15]

A method for producing a copolymer containing a polyimide and polyimide precursor, the method comprising the following steps:
(i) subjecting a first tetracarboxylic dianhydride or an acid/substituent adduct thereof to a condensation reaction with a first diamine compound for imidization to obtain a diamine oligomer having a repeating unit of a polyimide structure;
(ii) subjecting the diamine oligomer to a condensation reaction with a second tetracarboxylic dianhydride or an acid/substituent adduct thereof to synthesize a polyimide-imide precursor moiety having a polyimide block moiety; and
(iii) subjecting the polyimide-imide precursor moiety to a condensation reaction with a third tetracarboxylic dianhydride or an acid/substituent adduct thereof and a second diamine compound to synthesize a polyimide precursor moiety,

wherein the first tetracarboxylic dianhydride, the second tetracarboxylic dianhydride and the third tetracarboxylic dianhydride may be the same as or different from each other, at least one of the second tetracarboxylic dianhydride and the third tetracarboxylic dianhydride is in the form of an acid/substituent adduct having a photopolymerizable functional group, and the first diamine compound and the second diamine compound may be the same as or different from each other.

[16]

A method for producing a photosensitive resin composition, the method comprising:
producing a copolymer resin containing a polyimide and polyimide precursor by the method according to item 15; and
a step of mixing (A) 100 parts by weight of the copolymer resin containing the polyimide and polyimide precursor, (B) 0.5 to 30 parts by weight of a photopolymerization initiator, and (C) 100 to 1,000 parts by weight of a solvent to obtain a photosensitive resin composition.

### Advantageous Effects of Invention

According to the present disclosure, it is possible to provide a photosensitive resin composition which has low dielectric properties, low cure shrinkage and satisfactory storage stability, and exhibits reduced phase separation during coating, and is capable of forming a cured relief pattern with high resolution and high copper adhesion, and a method for producing a polyimide cured film and a polyimide cured film using the same.

### DESCRIPTION OF EMBODIMENTS

Hereinafter, embodiments of the present disclosure will be described in detail. Throughout the description, structures represented by the same reference numerals in general formulas may be independently selected and may be the same or different from each other, unless otherwise specified, when a plurality of structures are present in the molecule. Structures represented by common symbols in different general formulas are also independently selected and may be the same or different from each other, unless otherwise specified.

### <Photosensitive Resin Composition>

The photosensitive resin composition of the present disclosure comprises (A) 100 parts by weight of a specific copolymer resin containing a polyimide and polyimide precursor, (B) 0.5 to 30 parts by weight of a photopolymerization initiator, and (C) 100 to 1,000 parts by weight of a solvent. The photosensitive resin composition of the present disclosure may optionally include, in addition to the above components, (D) a silane coupling agent, (E) a radically polymerizable compound, (F) a thermal crosslinking agent, (G) a filler, and other components.

(A) Copolymer Resin containing Polyimide and Polyimide Precursor

The copolymer resin containing a polyimide and polyimide precursor (hereinafter also simply referred to as “copolymer resin”) preferably includes a structure represented by the following general formula (1):

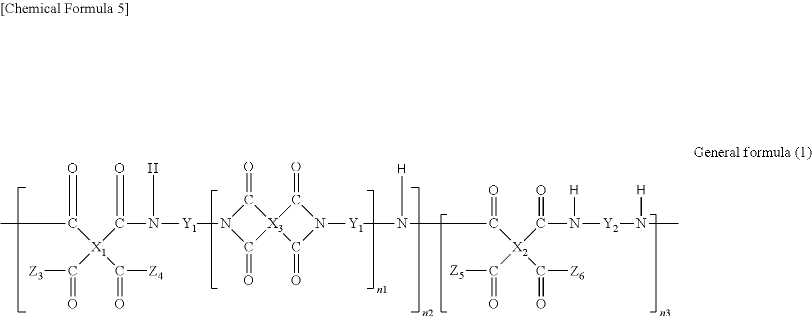

wherein, in formula (1), X₁, X₂ and X₃ are each independently a tetravalent organic group having 6 to 40 carbon atoms, Y₁ and Y₂ are each independently a divalent organic group having 6 to 40 carbon atoms, X₁, X₂ and X₃ may be the same or different, Y₁ and Y₂ may be the same or different, n₁ is an integer of 2 to 30, and n₂ and n₃ are each independently an integer of 2 to 150. In the present disclosure, a unit of n₁ of formula (1) is referred to as “polyimide block moiety”, a unit of n₂ is referred to as “polyimide-imide precursor moiety”, and a unit of n₃ is referred to as “polyimide precursor moiety”. In formula (1), for the sake of simplicity, only one polyimide-imide precursor moiety and one polyimide precursor moiety are shown, but the copolymer resin may have a plurality of polyimide-imide precursor moieties and a plurality of polyimide precursor moieties randomly arranged relative to each other.

In formula (1), Z₃, Z₄, Z₅ and Z₆ are each independently a monovalent organic group, at least one of them is a photopolymerizable functional group. The photopolymerizable functional group preferably contains a reactive unsaturated bond which polymerizes by light. It is more preferable that Z₃, Z₄, Z₅ and Z₆ form an ester bond together with a carbonyl group (—C(═O)—) to which they are directly bonded (hereinafter referred to as “ester bond type”) or forms an amide bond (hereinafter referred to as “amide bond type”). When Z₃, Z₄, Z₅ and Z₆ are ester bond type side chains, they can be represented as R₁ O—, R₂ O—, R₃ O— and R₄ O—, respectively, and when they are amide bond type side chains, they can be represented as R₁ NH—, R₂NH—, R₃ NH— and R₄ NH—, respectively. All Z₃, Z₄, Z₅ and Z₆ may be ester bond types or amide bond types, or a combination of ester bond types and amide bond types.

In formula (1), R₁, R₂, R₃ and R₄ are each independently a hydrogen atom or a monovalent organic group having 1 to 40 carbon atoms. However, at least one of R₁, R₂, R₃ and R₄ is a photopolymerizable functional group, and examples thereof include at least one group selected from a (meth)acryloyloxyalkyl group, an allyl group, an ethynyl group and a styryl group, and of these, a (meth)acryloyloxyalkyl group is more preferable. It is still more preferable that Z₃, Z₄, Z₅ and Z₆ contains a photopolymerizable functional group represented by the following general formula (2):

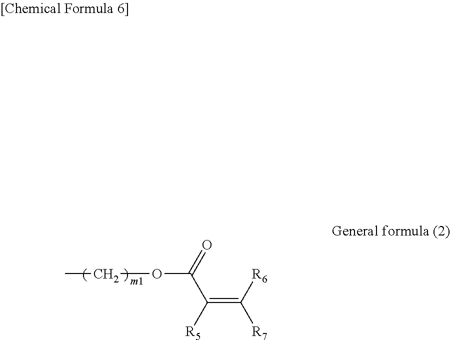

wherein, in formula (2), R₅, R₆ and R₇ are each independently a hydrogen atom or a monovalent organic group having 1 to 3 carbon atoms, and m₁ is an integer of 2 to 10. Examples of the monovalent organic group having 1 to 3 carbon atoms include a methyl group, an ethyl group, an n-propyl group and an isopropyl group, and a methyl group is preferable. R₅ is preferably a hydrogen atom or a methyl group, and R₆ and R₇ are preferably a hydrogen atom or a methyl group, and more preferably a hydrogen atom. m₁ is preferably an integer of 2 to 5, and more preferably an integer of 2 to 3. Z₃, Z₄, Z₅ and Z₆ are preferably ester bond types represented by R₁ O—, R₂ O—, R₃ O— and R₄ O—, amide bond types represented by R₁ NH—, R₂NH—, R₃ NH— and R₄NH—, or a combination of them, and it is still more preferable that R₁, R₂, R₃ and R₄ are each independently a photopolymerizable functional group represented by the above general formula (2).

In the copolymer resin containing a polyimide and polyimide precursor, the ratio of the number of mols of the polyimide-imide precursor moiety (unit of n₂) to the total number of mols of the polyimide-imide precursor moiety (unit of n₂) and the polyimide precursor moiety (unit of n₃) (hereinafter also referred to as “imide structure introduction ratio”) satisfies 0.10<n₂/(n₂+n₃)<0.90. This makes it possible to obtain a photosensitive resin composition which has low dielectric properties and low cure shrinkage in polyimide after curing, and satisfactory storage stability, and is capable of forming a cured relief pattern with high resolution.

By including the structure of the above general formula (1), it is possible to obtain a cured film which has satisfactory relief pattern resolution, low dielectric properties and low moisture permeability. Although not bound by theory, it is considered that, by having a polyimide block moiety (unit of n₁) and a polyimide precursor structure (i.e., imide precursor structure in units of n₂ and n₃) in the same molecule and having a polyimide-imide precursor moiety in a specific ratio, swelling of the exposed area is suppressed and the contrast with the unexposed area is easily ensured, leading to an improvement in resolution of the relief pattern. It is considered that since a part of the copolymer resin has a polyimide block moiety, the leaving moiety of the side chain structure is reduced during ring closure to suppress cure shrinkage, thus enabling the development of low dielectric properties. Further, by having the polyimide block moiety and the polyimide precursor structure in the same molecule, the polyimide structure having low solubility can exist stably in a photosensitive resin composition solution (hereinafter also referred to as “varnish”). It is considered that this prevents deterioration of the storage stability of the varnish. Meanwhile, when a varnish containing the polyimide precursor resin is heated to form an imide structure, photosensitive groups detached from the side chain structure remain in the varnish, resulting in large cure shrinkage.

From the viewpoints of the resolution, low dielectric properties and low cure shrinkage, the imide structure introduction ratio is preferably 0.10 to 0.90. From the viewpoint of the resolution, lower imide structure introduction rate is preferable, and from the viewpoints of low dielectric properties and low cure shrinkage, larger n₂/(n₂+n₃) is preferable, and therefore the imide structure introduction rate is more preferably 0.20 to 0.90, still more preferably 0.30 to 0.90, yet more preferably 0.40 to 0.90, particularly preferably 0.43 to 0.80, and particularly preferably 0.45 to 0.75.

From the viewpoints of the resolution, low dielectric properties and low cure shrinkage, the ratio of the copolymer resin represented by the above general formula (1) to the total weight of the copolymer resin containing a polyimide and polyimide precursor (A) is preferably 25 wt % or more, more preferably 35 wt % or more, still more preferably 50 wt % or more, particularly preferably 75 wt % or more, particularly preferably 90 wt % or more, particularly preferably 95 wt % or more, and most preferably 100 wt %.

From the viewpoints of the photosensitive properties and mechanical properties of the photosensitive resin composition, n₂ in the above general formula (1) is preferably an integer of 3 to 100, and more preferably an integer of 5 to 70. From the viewpoints of the photosensitive properties and mechanical properties, n₃ is preferably an integer of 3 to 100, and more preferably an integer of 5 to 70. From the viewpoints of the coatability and dielectric loss tangent, n₁ is preferably an integer of 2 to 30, and more preferably an integer of 5 to 20. The larger n₁, the higher the imide structure introduction ratio, and the better the dielectric loss tangent. Meanwhile, if n₁ is too large, the coatability deteriorates, and therefore the balance is important.

The tetravalent organic group represented by X₁, X₂ and X₃ in the above general formula (1) is preferably an organic group having 6 to 40 carbon atoms, and more preferably an aromatic group in which —COOR₁ and —COOR₂ groups and a —CONH— group are in the ortho-position to each other, or an alicyclic aliphatic group, in view of achieving both heat resistance and photosensitive properties. Specifically, the tetravalent organic group represented by X₁, X₂ and X₃ include, but is not limited to, an aromatic ring-containing organic group having 6 to 40 carbon atoms, for example, a group having a structure represented by the following general formula (3):

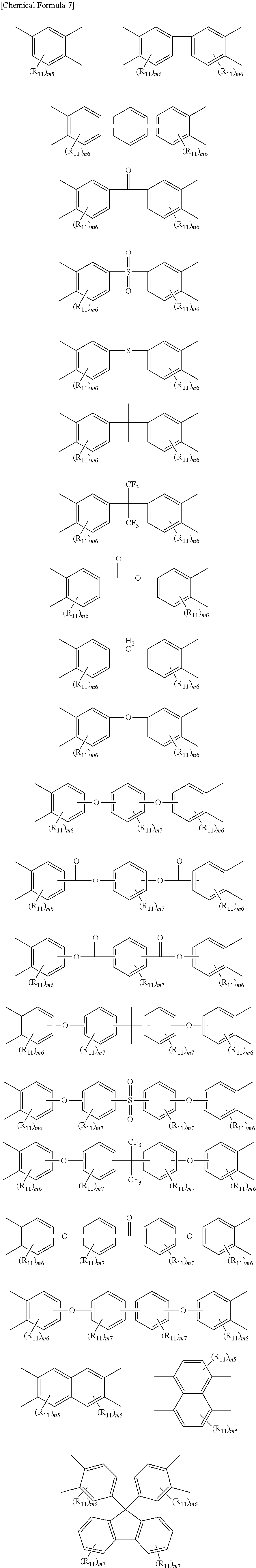

wherein, in formula (3), R₁ i is a monovalent group selected from the group consisting of a hydrogen atom, a fluorine atom, a C1 to C10 hydrocarbon group and a C1 to C10 fluorine-containing hydrocarbon group, m₅ is an integer of 1 to 2, m₆ is an integer of 1 to 3, and m₇ is an integer of 1 to 4. The tetravalent organic groups represented by X₁, X₂ and X₃ may be alone or a combination of two or more thereof. The X₁, X₂ and X₃ groups having a structure represented by the above formula (3) are particularly preferable in view of achieving both heat resistance and photosensitive properties.

X₁, X₂ and X₃ in the above general formula (1) preferably includes a structure represented by the following general formula (4) from the viewpoints of the resolution and low dielectric properties:

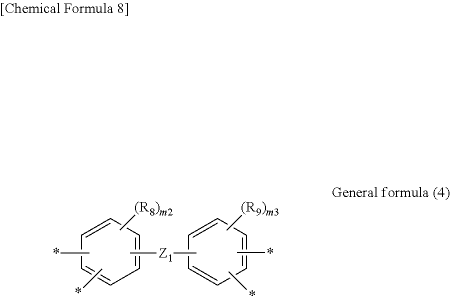

wherein R₈ and R₉ are each independently an organic group having 1 to 10 carbon atoms, m₂ and m₃ are an integer selected from 0 to 4 and satisfy m₂+m₃≥1, Z₁ is selected from the group consisting of a single bond, an organic group having 1 to 30 carbon atoms and an organic group containing a heteroatom, two of * mean bonding to the main chain of the resin, and the other two mean bonding to the side chain (i.e., Z₃—(C═O)— and Z₄—(C═O)—, or Z₅—(C═O)— and Z₆—(C═O)—) in the above general formula (1), and:

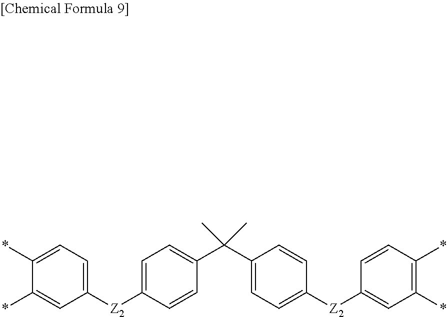

wherein Z₂ is selected from the group consisting of a single bond, an organic group having 1 to 30 carbon atoms and an organic group containing a heteroatom, two of * mean bonding to the main chain of the resin, and the other two mean bonding to the side chain in the above general formula (1).

The organic group having 1 to 10 carbon atoms represented by R₈ and R₉ of the above general formula (4) is preferably a linear or branched alkyl group. By introducing an alkyl group into the aromatic ring, the solubility of the copolymer resin (A) in a developing solution is improved and the contrast with the exposed area is easily ensured, leading to an improvement in resolution of the relief pattern. By introducing an alkyl group into the aromatic ring, the polarizability decreases, resulting in low dielectric properties.

From the viewpoint of the chemical resistance, R₈ and R₉ of the above general formula (4) are preferably organic groups having 1 to 4 carbon atoms, more preferably alkyl groups having 1 to 4 carbon atoms, for example, a methyl group, an ethyl group, a propyl group and a butyl group, and particularly preferably a methyl group.

It is more preferable that the structure represented by X₁, X₂ and X₃ in the above general formula (1) includes at least one structured selected from the group consisting of the following general formula (5):

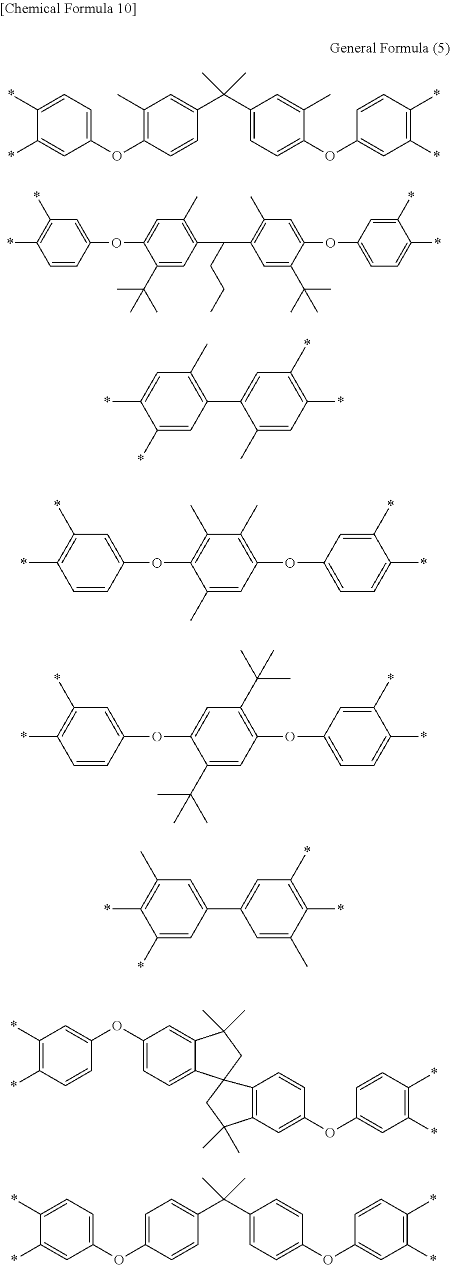

wherein two of * mean bonding to the main chain of the resin, and the other two mean bonding to the side chain in the above general formula (1). The structures of X₁, X₂ and X₃ in the above general formula (1) are not limited to the structures shown in (3), (4) and (5) above. The above structures may be alone or in combination of two or more thereof.

The divalent organic group represented by Y₁ and Y₂ in the above general formula (1), includes aliphatic chains (alkylene groups) having 6 to 40 carbon atoms, preferably 6 to 20 carbon atoms, for example, a heptylene group, an octylene group, a nonylene group, a decylene group and an undecylene group; and aromatic groups having 6 to 40 carbon atoms. In view of achieving both heat resistance and photosensitive properties, an aromatic group is preferable and an aromatic group having 6 to 40 carbon atoms is more preferable, and examples thereof include, but are not limited to, a group having a structure represented by the following general formula (6):

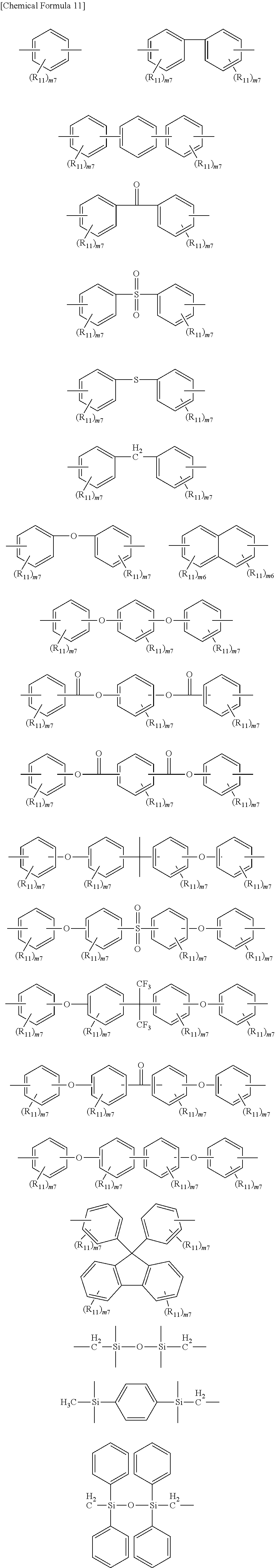

wherein, in formula (6), R₁₁ is a monovalent group selected from the group consisting of a hydrogen atom, a fluorine atom, a C1 to C10 hydrocarbon group and a C1 to C10 fluorine-containing hydrocarbon group, m₆ is an integer of 1 to 3, and m₇ is an integer of 1 to 4. The divalent organic groups represented by Y₁ and Y₂ may be alone or in combination of two or more thereof. In view of achieving both heat resistance and photosensitive properties, Y₁ and Y₂ groups having the structure represented by the above formula (6) is particularly preferable.

From the viewpoints of the resolution and low dielectric properties, Y₁ and/or Y₂ in the above general formula (1) preferably include(s) a structure represented by the following general formula (7):

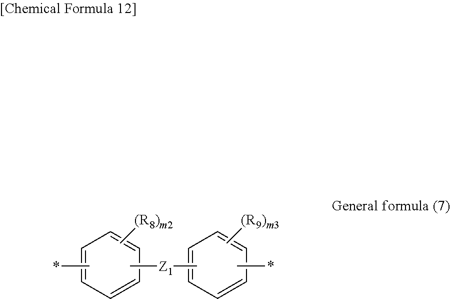

wherein R₈ and R₉ are each independently an organic group having 1 to 10 carbon atoms, m₂ and m₃ are an integer selected from 0 to 4 and satisfy m₂+m₃≥1, Z₁ is selected from the group consisting of a single bond, an organic group having 1 to 30 carbon atoms and an organic group containing a heteroatom, and * means bonding to the main chain of the resin.

The organic group having 1 to 10 carbon atoms represented by R₈ and R₉ of the above general formula (7) is preferably a linear or branched alkyl group. By introducing an alkyl group into the aromatic ring, the solubility of the copolymer resin (A) in a developing solution is improved and the contrast with the exposed area is easily ensured, leading to an improvement in resolution of the relief pattern. By introducing an alkyl group into the aromatic ring, the polarizability decreases, resulting in low dielectric properties.

From the viewpoint of the chemical resistance, R₈ and R₉ of the above general formula (7) are preferably organic groups having 1 to 4 carbon atoms, more preferably alkyl groups having 1 to 4 carbon atoms, for example, a methyl group, an ethyl group, a propyl group and a butyl group, and particularly preferably a methyl group. As an example of the above general formula (7), it is preferable to include at least one structure selected from the group consisting of the following general formula (8):

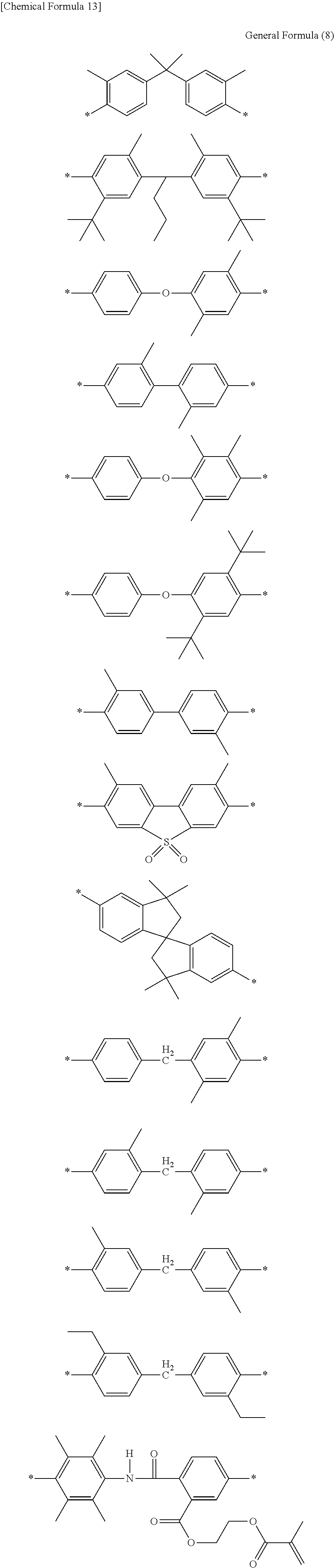

wherein * means bonding to the main chain of the resin.

The structures represented by Y₁ and Y₂ in the above general formula (1) preferably include at least one structure selected from the group consisting of the following general formula (9):

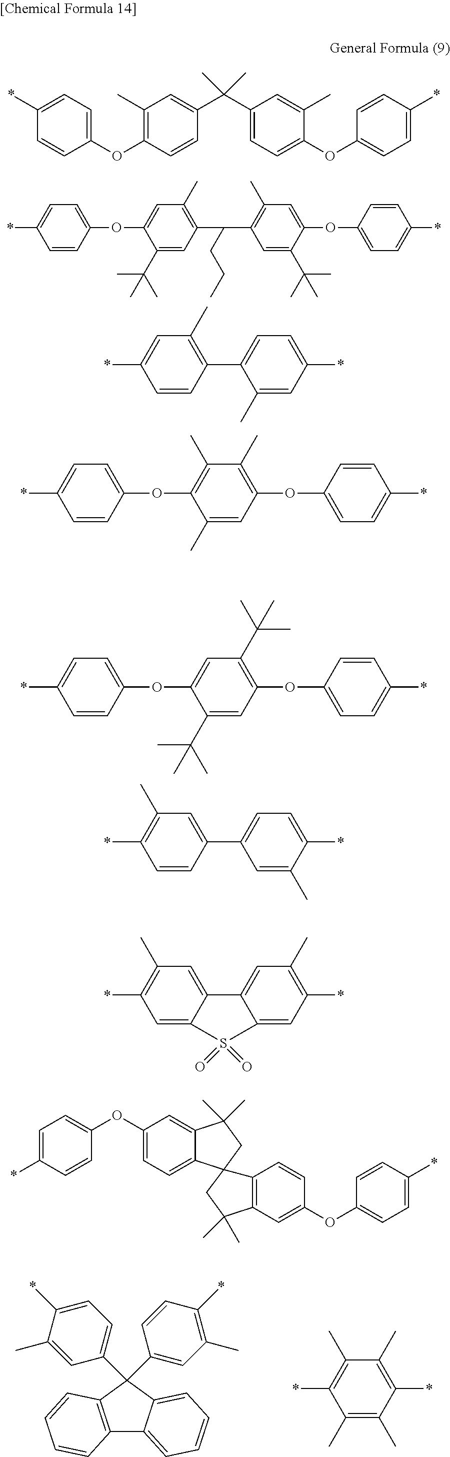

wherein * means bonding to the main chain of the resin. The structures of Y₁ and Y₂ in the above general formula (1) are not limited to the structures shown in (6) to (9) above. The above structures may be alone or in combination of two or more thereof.

From the viewpoint of inhibiting copper corrosion in the heat curing step, it is preferable that at least one or all of X₁, X₂, X₃, Y₁, Y₂ in the above general formula (1) do not contain a halogen atom. That is, it is more preferable that the copolymer resin (A) does not contain a halogen atom.

In the copolymer resin (A), it is preferable that at least one of X₁, X₂ and X₃ which are skeletal components derived from a tetracarboxylic acid compound, and Y₁ and Y₂ which are skeletal components derived from a diamine compound has two or more benzene rings. Two or more benzene rings may be bonded to each other directly or through a divalent or higher organic group. The number of benzene rings may be 3 or more, or 4 or more, 6 or less, 5 or less, or 4 or less, and is more preferably 4. It is more preferable that the total number of carbon atoms constituting X₁, X₂ and X₃ which indicate structures derived from a tetracarboxylic acid compound, and Y₁ and Y₂ which indicate structures derived from a diamine compound is more than 39. When the copolymer resin (A) has such a structure, the resolution of the negative photosensitive resin composition is maintained, and the resulting cured relief pattern tends to have low dielectric properties.

In the photosensitive resin composition of the present disclosure, the imide group concentration U in the polyimide of the cured polyimide film obtained by heating and curing the photosensitive resin composition is 12% by weight to 26% by weight. As used herein, the term “imide group concentration U” refers to the ratio of the molecular weight of imide groups to the molecular weight of repeating units including structures derived from tetracarboxylic dianhydride and a diamine compound in polyimide of a polyimide cured film obtained by heating and curing the photosensitive resin composition at 350° C. The condition of heating and curing at 350° C. is intended to clarify the criteria for the imide group concentration T by using, as the standard, the state where the copolymer resin (A) is almost 100% imidized, and it is not intended that the photosensitive resin composition is heated and cured at 350° C. in actual use.

If the imide group concentration U is 12.0% by weight or more, the resolution of the relief pattern tends to be satisfactory. The imide group concentration U is preferably 15% by weight or more, and more preferably 17.5% by weight or more. Meanwhile, when the imide group concentration U is 26% by weight or less, the dielectric loss tangent of the resulting polyimide cured film tends to be satisfactory. The imide group concentration U is more preferably 23.0% by weight or less, and still more preferably 20.5% by weight or less.

The imide group concentration U in the repeating unit of the polyimide cured film is represented by the following formula (I):

$$70.02 \times 2 / [ Mw ( A ) + Mw ( B ) - 36 ] \times 100 \qquad ( I )$$

wherein, in formula (I), Mw(A) represents the molecular weight of tetracarboxylic dianhydride and Mw(B) represents the molecular weight of diamine, using the molecular weight of the tetracarboxylic dianhydride and the molecular weight of the diamine compound used during preparation of the copolymer resin (A). When using two or more types of tetracarboxylic dianhydrides and/or diamine compounds, for example, in the case of preparing using two types of tetracarboxylic dianhydrides and/or diamines, the imide group concentration is represented by the following formula (II):

$$70.02 \times 2 / [ Mw ( A 1 ) \times {a}_{1} + Mw ( A 2 ) \times {a}_{2} + Mw ( B 1 ) \times {b}_{1} + M w ( B 2 ) \times {b}_{2} - 36 ] \times 100 \qquad ( II )$$

wherein, in formula (II), Mw(A1) represents the molecular weight of a first tetracarboxylic dianhydride, Mw(A2) represents the molecular weight of a second tetracarboxylic dianhydride, a₁ represents a constant of a first tetracarboxylic dianhydride, a₂ represents a constant of a second tetracarboxylic dianhydride, Mw(B1) represents the molecular weight of a first diamine compound, Mw(B2) represents the molecular weight of a second diamine compound, b₁ represents a constant of a first diamine compound, and b2 represents a constant of a second diamine compound, in which a₁, a₂, b₁ and b₂ satisfy a₁+a₂=1 and b₁+b₂=1, respectively. When using three or more types of tetracarboxylic dianhydrides and/or diamines, it is possible to obtain in the same manner. When using tetracarboxylic acid and/or tetracarboxylic acid dichloride as starting materials, calculation is carried out using the weight of the corresponding tetracarboxylic acid dianhydride.

The copolymer resin (A) may have the other reactive substituents which crosslink by heat or light at the end of the main chain, and are different from the photopolymerizable functional group included in the repeating units. The terminal reactive substituent is preferably a group having a reactive unsaturated bond capable of reacting with heat or light to crosslink with each other. The copolymer resin (A) preferably has at least one of the structures represented by the following general formulas (E1) and (E2) at the end of the main chain. When the copolymer resin (A) has these reactive substituents at the end of the main chain, it is possible to obtain a high-resolution negative photosensitive resin composition having improved residual film ratio after curing or dielectric properties.

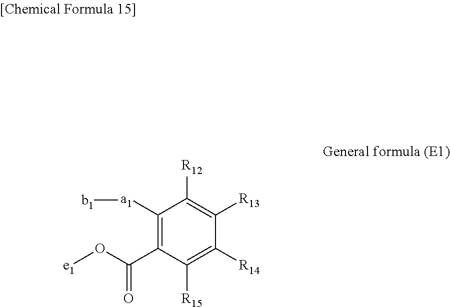

In formula (E1), a₁ contains at least one bond selected from the group consisting of an amide bond, an imide bond, a urea bond and a urethane bond, b₁ is a reactive substituent which crosslinks by heat or light, and e₁ is a monovalent organic group having 1 to 30 carbon atoms. R₁₂ and R₁₅ are each independently a hydrogen atom or a monovalent organic group having 1 to 30 carbon atoms, and R₁₃ and R₁₄ are each independently a hydrogen atom, a monovalent or a divalent organic group having 1 to 30 carbon atoms, or both are part of an aromatic ring or an aliphatic ring. However, both R₁₃ and R₁₄ are not hydrogen atoms, and R₁₃ and R₁₄ are linked to the main chain structure.

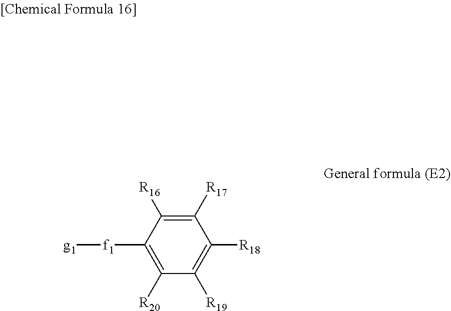

In formula (E2), fi contains at least one bond selected from the group consisting of an amide bond, an imide bond, a urea bond, a urethane bond and an ester bond, g i is a reactive substituent which crosslinks by heat or light, and R₁₆ to R₂₀ are each independently a hydrogen atom, a monovalent or divalent organic group having 1 to 30 carbon atoms, or together form an aromatic ring or an aliphatic ring. However, R₁₇, R₁₈ and R₁₉ are not simultaneously hydrogen atoms, and any one or two of R₁₇, R₁₈ and R₁₉ are linked to the main chain structure. It is preferable that fi contains at least one group selected from the group consisting of an amide group, an imide bond, a urea group and a urethane group, since it is easily crosslinked and is less susceptible to hydrolysis and therefore has high chemical resistance.

The reactive substituent b₁ which crosslinks by heat or light is preferably at least one selected from, for example, an acrylic group, a methacrylic group, a vinyl group, an alkenyl group, a cycloalkenyl group, an alkadienyl group, a cycloalkadienyl group, a styryl group, an ethynyl group, an imino group, an isocyanato group, a cyanato group, a cycloalkyl group, an epoxy group, an oxetanyl group, a carbonate group, a hydroxyl group, a mercapto group, a methylol group and an alkoxyalkyl group. From the viewpoint of the film thickness uniformity, b₁ is preferably at least one selected from an acrylic group, a methacrylic group, a vinyl group, an alkenyl group, a cycloalkenyl group, an alkadienyl group, a cycloalkadienyl group, a styryl group and an ethynyl group. A methacryl group is particularly preferable.

The reactive substituent gi which crosslinks by heat or light is, for example, at least one selected from an acrylic group, a methacrylic group, a vinyl group, an alkenyl group, a cycloalkenyl group, an alkadienyl group, a cycloalkadienyl group, a styryl group, an ethynyl group, an imino group, an isocyanato group, a cyanato group, a cycloalkyl group, an epoxy group, an oxetanyl group, a carbonate group, a hydroxyl group, a mercapto group, a methylol group and an alkoxyalkyl group. From the viewpoint of the film thickness uniformity, gi is preferably at least one selected from an acrylic group, a methacrylic group, a vinyl group, an alkenyl group, a cycloalkenyl group, an alkadienyl group, a cycloalkadienyl group, a styryl group and an ethynyl group. g1 is particularly preferably a methacryl group.

Specific examples of the compound having a reactive substituent which reacts by heat or light and a site which also reacts with a carboxyl group, and the main chain end of the polyimide precursor modified with a reactive substituent are shown below.

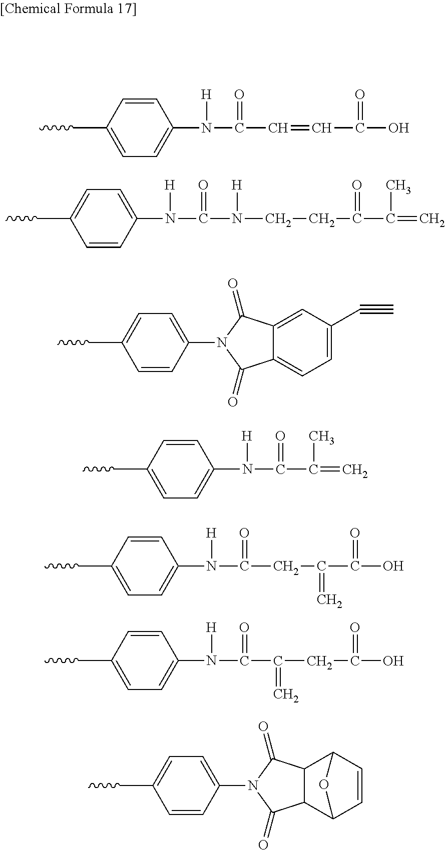

Method for Producing (A) Copolymer containing Polyimide and Polyimide Precursor The method for producing a copolymer containing a polyimide and polyimide precursor comprises the following steps:
(i) subjecting a first tetracarboxylic dianhydride or an acid/substituent adduct thereof to a condensation reaction with a first diamine compound for imidization to obtain a diamine oligomer having a repeating unit of a polyimide structure;
(ii) subjecting the diamine oligomer to a condensation reaction with a second tetracarboxylic dianhydride or an acid/substituent adduct thereof to synthesize a polyimide-imide precursor moiety having a polyimide block moiety; and
(iii) subjecting the polyimide-imide precursor moiety to a condensation reaction with a third tetracarboxylic dianhydride or an acid/substituent adduct thereof and a second diamine compound to synthesize a polyimide precursor moiety. The first tetracarboxylic dianhydride, the second tetracarboxylic dianhydride and the third tetracarboxylic dianhydride may be the same as or different from each other, at least one of the second tetracarboxylic dianhydride and the third tetracarboxylic dianhydride is in the form of an acid/substituent adduct having a photopolymerizable functional group, and the first diamine compound and the second diamine compound may be the same as or different from each other.

### (Preparation of Acid/Substituent Adduct)

The first, second and third tetracarboxylic dianhydrides used in steps (i), (ii) and (iii) may be in the form of an acid dianhydride, or may be in the form having an acid moiety (HO—C(═O)—) and a substituent addition moiety (Z—C(═O)—, Z corresponds to Z₃ to Z₆ in the general formula (1)) in which a substituent of the side chain has been added in advance to the acid dianhydride (also referred to as “acid/substituent adduct” in the present disclosure). However, at least one of the second and third tetracarboxylic dianhydrides is in the form of an acid/substituent adduct having a photopolymerizable functional group. As mentioned above, Z₃, Z₄, Z₅ and Z₆ can be of the ester bond type (hereinafter also referred to as “acid/ester body”) or the amide bond type (hereinafter also referred to as “acid/amide body”), and an ester bond type or an amide bond type polyimide precursor can be prepared by using such acid/ester body or acid/amide body.

Examples of the tetracarboxylic dianhydride having a tetravalent organic group X₁ having 6 to 40 carbon atoms which is preferably used for preparing an ester bond type or amide bond type polyimide precursor include, in addition to the tetracarboxylic dianhydride derived from the structure listed above, but are not limited to, pyromellitic anhydride, diphenyl ether-3,3′,4,4′-tetracarboxylic dianhydride, benzophenone-3,3′,4,4′-tetracarboxylic dianhydride, biphenyl-3,3′,4,4′-tetracarboxylic dianhydride, diphenylsulfone-3,3′,4,4′-tetracarboxylic dianhydride, diphenylmethane-3,3′,4,4′-tetracarboxylic dianhydride, 2,2-bis(3,4-phthalic anhydride)propane, 2,2-bis(3,4-phthalic anhydride)-1,1,1,3,3,3-hexafluoropropane, 4,4′-(4,4′-isopropylidenediphenoxy)diphthalic anhydride, 4,4′-bis(3,4-dicarboxyphenoxy)benzophenone dianhydride and the like. The tetracarboxylic dianhydrides may be used alone or in combination of two or more thereof.

Using these tetracarboxylic dianhydrides having a tetravalent organic group X₁ having 6 to 40 carbon atoms, tetracarboxylic dianhydrides are reacted with a compound having a reactive substituent (photopolymerizable functional group) which reacts with light (also referred to as “substituent-introduced compound” in the present disclosure), thus making it possible to obtain an esterified or amidated tetracarboxylic acid (acid/ester body or acid/amide body). It is also possible to introduce a reactive substituent into the end of the main chain of the copolymer (A) using the above-mentioned substituent-introduced compound. The order of reactions varies depending on the method of introduction.

Examples of the substituent-introduced compound (also referred to as a “first substituent-introduced compound” in the present disclosure) which is suitably used for the synthesis of an esterified tetracarboxylic acid (acid/ester body) include alcohols having a photopolymerizable functional group. The alcohols having a photopolymerizable functional group preferably include alcohols including a structure of the general formula (2), for example, 2-hydroxyethyl methacrylate (HEMA), 2-acryloyloxyethyl alcohol, 1-acryloyloxy-3-propyl alcohol, 2-acrylamidoethyl alcohol, methylol vinyl ketone, 2-hydroxyethyl vinyl ketone, 2-hydroxy-3-methoxypropyl acrylate, 2-hydroxy-3-butoxypropyl acrylate, 2-hydroxy-3-phenoxypropyl acrylate, 2-hydroxy-3-butoxypropyl acrylate, 2-hydroxy-3-t-butoxypropyl acrylate, 2-hydroxy-3-cyclohexyloxypropylacrylate, 2-mathacryloyloxyethyl alcohol, 1-mathacryloyloxy-3-propyl alcohol, 2-methacrylamidoethyl alcohol, 2-hydroxy-3-methoxypropyl methacrylate, 2-hydroxy-3-butoxypropyl methacrylate, 2-hydroxy-3-phenoxypropyl methacrylate, 2-hydroxy-3-butoxypropyl methacrylate, 2-hydroxy-3-t-butoxypropyl methacrylate and 2-hydroxy-3-cyclohexyloxypropyl methacrylate.

As the saturated aliphatic alcohols which can be optionally used together with the above-mentioned alcohols having a photopolymerizable functional group, saturated aliphatic alcohols having 1 to 4 carbon atoms are preferable. Specific examples thereof include methanol, ethanol, n-propanol, isopropanol, n-butanol, tert-butanol and the like.

Examples of the substituent-introduced compound (also referred to as a “first substituent-introduced compound” in the present disclosure) which is suitably used for the synthesis of an amidated tetracarboxylic acid (acid/amide body) include amines having a photopolymerizable functional group. Preferred examples of amines having a photopolymerizable functional group include amines including a structure of the general formula (2), for example, 2-aminoethyl methacrylate, 2-aminoethyl acrylate, 2-(tert-butylamino)ethyl methacrylate and the like.

By mixing the tetracarboxylic dianhydride and the first substituent-introduced compound with stirring, preferably in the presence of a basic catalyst such as pyridine, preferably in a suitable reaction solvent, at a temperature of 20 to 50° C. for 4 to 10 hours, the addition of the substituent to the acid anhydride (for example, an esterification or amidation reaction) proceeds, thus making it possible to obtain a desired acid/substituent adduct.

As the reaction solvent, those capable of completely dissolving the tetracarboxylic dianhydride and first substituent-introduced compound as starting materials as well as the acid/substituent adduct as the product are preferable. More preferably, the solvent also completely dissolves the polyimide precursor which is an amide polycondensation product of the acid/substituent adduct and diamine. Examples thereof include N-methyl-2-pyrrolidone, N,N-dimethylacetamide, N,N-dimethylformamide, dimethyl sulfoxide, tetramethylurea, ketones, esters, lactones, ethers, halogenated hydrocarbons, hydrocarbons and the like. Specific examples thereof include ketones such as acetone, methyl ethyl ketone, methyl isobutyl ketone and cyclohexanone. Examples of esters include methyl acetate, ethyl acetate, butyl acetate, diethyl oxalate and the like. Examples of lactones include γ-butyrolactone and the like. Examples of ethers include ethylene glycol dimethyl ether, diethylene glycol dimethyl ether, tetrahydrofuran and the like. Examples of halogenated hydrocarbons include dichloromethane, 1,2-dichloroethane, 1,4-dichlorobutane, chlorobenzene, o-dichlorobenzene and the like. Examples of hydrocarbons include hexane, heptane, benzene, toluene, xylene and the like. These may be used alone or in combination of two or more thereof as necessary.

### (Preparation of Diamine Oligomer)

### Step (i):

A first tetracarboxylic dianhydride or an acid/substituent adduct thereof is subjected to a condensation reaction with a first diamine compound for imidization, thus making it possible to obtain a diamine oligomer having a repeating unit of a polyimide structure. The first tetracarboxylic dianhydride used in the condensation reaction is preferably in the form of an acid dianhydride rather than in the form of an acid/substituent adduct, from the viewpoint of increasing the imide ring closure ratio. For example, a first tetracarboxylic acid dianhydride having a tetravalent organic group X₁ having 6 to 40 carbon atoms and an excess amount of a first diamine compound having a divalent organic group Y₁ having 6 to 40 carbon atoms are subjected to a condensation reaction, thus making it possible to perform heat ring-closure. The imidization conditions are not limited, but may be, for example, heating at 160° C. or higher and 300° C. or lower for 1 hour to 10 hours. The higher the imide ring closure ratio, the more preferable. The imide ring closure ratio is not limited, but is preferably 90% or more, 95% or more, and more preferably 99% or more or 100%.

Examples of the first diamine compound having a divalent organic group Y₁ having 6 to 40 carbon atoms, which is a starting material of a diamine oligomer having a polyimide structure, include diamines having an aliphatic chain (alkylene group) having 6 to 40 carbon atoms, preferably 6 to 20 carbon atoms, for example, 1,7-diaminoheptane, 1,10-diaminodecane, 1,11-diaminoundecane and 1,12-diaminododecane; and diamines having an aromatic group having 6 to 40 carbon atoms. Examples of diamines having an aromatic group include, in addition to the diamines derived from the structures listed above, p-phenylenediamine, m-phenylenediamine, 4,4-diaminodiphenyl ether, 3,4′-diaminodiphenyl ether, 3,3′-diaminodiphenyl ether, 4,4′-diaminodiphenyl sulfide, 3,4′-diaminodiphenyl sulfide, 3,3′-diaminodiphenyl sulfide, 4,4′-diaminodiphenylsulfone, 3,4′-diaminodiphenylsulfone, 3,3′-diaminodiphenylsulfone, 4,4′-diaminobiphenyl, 3,4′-diaminobiphenyl, 3,3′-diaminobiphenyl, 4,4′-diaminobenzophenone, 3,4′-diaminobenzophenone, 3,3′-diaminobenzophenone, 4,4′-diaminodiphenylmethane, 3,4′-diaminodiphenylmethane, 3,3′-diaminodiphenylmethane, 1,4-bis(4-aminophenoxy)benzene, 1,3-bis(4-aminophenoxy)benzene, 1,3-bis(3-aminophenoxy)benzene, bis[4-(4-aminophenoxy)phenyl]sulfone, bis[4-(3-aminophenoxy)phenyl]sulfone, 4,4-bis(4-aminophenoxy)biphenyl, 4,4-bis(3-aminophenoxy)biphenyl, bis[4-(4-aminophenoxy)phenyl]ether, bis[4-(3-aminophenoxy)phenyl]ether, 1,4-bis(4-aminophenyl)benzene, 1,3-bis(4-aminophenyl)benzene, 9,10-bis(4-aminophenyl)anthracene, 2,2-bis(4-aminophenyl)propane, 2,2-bis(4-aminophenyl)hexafluoropropane, 2,2-bis[4-(4-aminophenoxy)phenyl]propane, 2,2-bis[4-(4-aminophenoxy)phenyl]hexafluoropropane, 1,4-bis(3-aminopropyldimethylsilyl)benzene, ortho-tolidine sulfone, 9,9-bis(4-aminophenyl)fluorene and bis{4-(4-aminophenoxy)phenyl}ketone, and those in which a part of hydrogen atoms on the benzene ring are substituted with an alkyl chain such as a methyl group or an ethyl group, for example, 2,2′-dimethyl-4,4′-diaminodiphenylmethane, 3,3′-dimethoxy-4,4′-diaminobiphenyl, 3,3′-dichloro-4,4′-diaminobiphenyl, and mixtures thereof. However, diamine compounds are not limited to them. These may be used alone, or may be used in combination of two or more thereof. These diamine compounds can also be used as the second diamine compound.

### (Preparation of Copolymer Containing Polyimide and Polyimide Precursor)

### Step (ii):

The diamine oligomer obtained above as diamine is subjected to a condensation reaction with a second tetracarboxylic dianhydride or an acid/substituent adduct thereof, thus making it possible to synthesize a polyimide-imide precursor moiety (unit of n₂) having a polyimide block moiety (unit of n₁). The second tetracarboxylic dianhydride is preferably in the form of an acid/substituent adduct having a photopolymerizable functional group. The acid/substituent adduct is typically in a solution state dissolved in a reaction solvent after preparation of the acid/substituent adduct by the above method. Preferably, under ice cooling, a suitable dehydration condensation agent is added, followed by mixing to convert the acid/substituent adduct into a polyacid anhydride. Next, a solvent containing the diamine oligomer obtained above dissolved or dispersed therein is added dropwise thereto, and both are subjected to amide polycondensation to obtain a polyimide-imide precursor moiety (unit of n₂). Diaminosiloxanes may be used in combination with the diamines having a divalent organic group Y₁, which are starting materials for the diamine oligomer having a polyimide structure. Examples of the dehydration condensation agent include dicyclohexylcarbodiimide (DCC), 1-ethoxycarbonyl-2-ethoxy-1,2-dihydroquinoline, 1,1-carbonyldioxy-di-1,2,3-benzotriazole, N,N′-disuccinimidyl carbonate and the like. As mentioned above, a polyacid anhydride as an intermediate is obtained.

Step (iii):

The polyimide-imide precursor moiety thus obtained is further subjected to a condensation reaction with a third tetracarboxylic dianhydride or an acid/substituent adduct thereof and a second diamine compound, thus making it possible to synthesize a polyimide precursor moiety (unit of n₃). When the second tetracarboxylic dianhydride (or an acid/substituent adduct thereof) and the third tetracarboxylic dianhydride (or an acid/substituent adduct thereof) are identical to each other, an excess amount of the second tetracarboxylic dianhydride (or an acid/substituent adduct thereof) present in the reaction solvent after synthesis of the polyimide-imide precursor moiety may be used as it is as the third tetracarboxylic dianhydride (or an acid/substituent adduct thereof). The desired tetracarboxylic dianhydride (or an acid/substituent adduct thereof) may be added in the system. When the first diamine compound and the second diamine compound are identical to each other, an excess amount of the first diamine compound present in the reaction solvent after synthesis of the diamine oligomer may be used as it is as the second diamine compound. A desired diamine compound may be added in the system.

### (Formation of Reactive Resin End)

It is possible to introduce other reactive substituents, which are polymerized by heat or light, and are different from the photopolymerizable functional groups included in the repeating units of the copolymer (A) into the end of the main chain, by the following method comprising:
(1) reacting a second and/or third tetracarboxylic dianhydride(s) with a first substituent-introduced compound having a photopolymerizable functional group, followed by reacting with a second substituent-introduced compound having a reactive substituent which reacts by heat or light and is different from the first substituent-introduced compound to prepare an acid/substituent adduct having a photopolymerizable functional group and a reactive substituent, or reacting a second and/or third tetracarboxylic dianhydride(s) with a second substituent-introduced compound, followed by reacting with a first substituent-introduced compound to obtain an acid/substituent adduct having a photopolymerizable functional group and a reactive substituent; and/or
(2) reacting a diamine oligomer with a second substituent-introduced compound to prepare a diamine oligomer having a second reactive substituent; and
(3) carrying out steps (ii) and (iii) in the method for producing a copolymer (A) using the acid/substituent adduct having a photopolymerizable functional group and a reactive substituent obtained in (1) above, and/or the diamine oligomer having a reactive substituent obtained in (2) above, thus making it possible to introduce reactive substituents derived from the second substituent-introduced compound into the acid and and/or amine end of the main chain of copolymer (A).

The second substituent-introduced compound is preferably a compound which introduces the structures represented by the above general formulas (E1) and (E2), and examples thereof include, but are not limited to, 2-isocyanatoethyl acrylate, 2-isocyanatoethyl methacrylate, 2-(2-methacryloyloxyethyloxy)ethyl isocyanate, 1,1-(bisacryloyloxymethyl)ethyl isocyanate, allylamine and methacrylic acid chloride.

To improve the adhesion between the photosensitive resin layer formed on the substrate by coating the photosensitive resin composition on the substrate and various substrates, during the preparation of the copolymer resin containing a polyimide and polyimide precursor (A), it is also possible to copolymerize diaminosiloxanes such as 1,3-bis(3-aminopropyl)tetramethyldisiloxane and 1,3-bis(3-aminopropyl)tetraphenyldisiloxane.

After completion of the amide polycondensation reaction, water-absorbing by-products of the dehydration condensation agent coexisting in the reaction solution are optionally filtered out, and then an appropriate poor solvent (e.g., water, aliphatic lower alcohol, mixed solution thereof, etc.) is added to the solution containing the polymer component to precipitate the polymer component, and as necessary, the polymer is purified by repeating operations such as redissolution and reprecipitation, followed by vacuum drying to isolate the objective the copolymer resin containing a polyimide and polyimide precursor (A). To improve the degree of purification, the polymer solution may be passed through a column packed with anion and/or cation exchange resins swollen with an appropriate organic solvent to remove ionic impurities.

The weight-average molecular weight of the copolymer resin containing a polyimide and polyimide precursor (A) is preferably 8,000 to 150,000, more preferably 9,000 to 50,000, and particularly preferably 18,000 to 40,000, when measured as a polystyrene-equivalent weight-average molecular weight by gel permeation chromatography (GPC) from the viewpoint of the heat resistance and mechanical properties of the film obtained after a heat treatment. The weight-average molecular weight is preferably 8,000 or more because of satisfactory mechanical properties, meanwhile, the weight-average molecular weight is preferably 150,000 or less because of satisfactory dispersibility in a developing solution and resolution performance of the relief pattern. Tetrahydrofuran and N-methyl-2-pyrrolidone are recommended as a developing solvent for gel permeation chromatography. The molecular weight is determined from a calibration curve prepared using standard monodisperse polystyrene. It is recommended to select the standard monodisperse polystyrene from an organic solvent-based standard sample STANDARD SM-105 manufactured by Showa Denko K.K.

### (B) Photopolymerization Initiator

The photopolymerization initiator (B) is a compound capable of polymerizing a compound having an ethylenically unsaturated group or the like by generating radicals with active light.

Examples of the initiator which generates radicals with active light include compounds including structures such as benzophenone, N-alkylaminoacetophenone, oxime ester, acridine and phosphine oxide. Examples thereof include, but are not limited to, aromatic ketones such as benzophenone, N,N,N′,N′-tetramethyl-4,4′-diaminobenzophenone (Michler's ketone), N,N,N′,N′-tetraethyl-4,4′-diaminobenzophenone, 4-methoxy-4′-dimethylaminobenzophenone, 2-benzyl-2-dimethylamino-1-(morpholinophenyl)-butanone-1, 2-methyl—[4-(methylthio)phenyl]-2-morpholino-propanone-1, acrylated benzophenone and 4-benzoyl-4′-methyldiphenyl sulfide; benzoin ether compounds such as benzoin methyl ether, benzoin ethyl ether and benzoin phenyl ether; benzoin compounds such as benzoin, methylbenzoin and ethylbenzoin; oxime ester compounds such as 1,2-octanedione, 1-[4-(phenylthio)-, 2-(0-benzoyloxime)], ethanone, 1-[9-ethyl-6-(2-methylbenzoyl)-9H-carbazol-3-yl]-,1-(0-acetyloxime) (Irgacure Oxe02, manufactured by BASF Japan Ltd.), 1-[4-(phenylthio)phenyl]-3-cyclopentylpropane-1,2-dione-2-(o-benzoyloxime) (PBG305 manufactured by Changzhou Tronly New Electronic Materials Co., Ltd.), 1,2-propanedione, 3-cyclohexyl-1-[9-ethyl-6-(2-furanylcarbonyl)-9H-carbazol-3-yl]-,2-(O-acetyloxime) (TR-PBG-326, product name, manufactured by Nikko Chemtech Co., Ltd.); benzyl derivatives such as benzyl dimethyl ketal; acridine derivatives such as 9-phenylacridine and 1,7-bis(9,9′-acridinyl)heptane; N-phenylglycine derivatives such as N-phenylglycine; coumarin compounds; oxazole compounds; and phosphine oxide compounds such as 2,4,6-trimethylbenzoyl-diphenyl-phosphine oxide. The polymerization initiator (C) described above can be used alone or in combination of two or more thereof. Of the photopolymerization initiators mentioned above, oxime ester compounds are more preferable from the viewpoint of the resolution.

The amount of the photopolymerization initiator mixed is 0.5 part by weight or more and 30 parts by weight or less, preferably 3 parts by weight or more and 15 parts by weight or less, relative to 100 parts by weight of the copolymer resin containing a polyimide and polyimide precursor (A) The mixing amount is 0.5 part by weight or more from the viewpoint of the photosensitivity or patterning properties, meanwhile, the mixing amount is preferably 30 parts by weight or less from the viewpoint of the physical properties of the photosensitive resin layer after curing the photosensitive resin composition.

### (C) Solvent

The solvent (C) is not limited as long as it can uniformly dissolve or suspend the copolymer resin containing a polyimide and polyimide precursor (A) and the photopolymerization initiator (B). Examples of such solvent include γ-butyrolactone, dimethyl sulfoxide, tetrahydrofurfuryl alcohol, ethyl acetoacetate, N,N-dimethylacetoacetamide, $-caprolactone, 1,3-dimethyl-2-imidazolidinone, 3-methoxy-N,N-dimethylpropanamide, 3-butoxy-N,N-dimethylpropanamide, N,N-dimethylformamide, N-methyl-2-pyrrolidone, N-ethyl-2-pyrrolidone, N,N-dimethylacetamide and the like. These solvents may be used alone or in combination of two or more thereof.

The solvent can be used in the amount within a range of, for example, 30 to 1,500 parts by weight, and preferably 100 to 1,000 parts by weight, relative to 100 parts by weight of the copolymer resin containing a polyimide and polyimide precursor (A) according to the desired coating thickness and viscosity of the photosensitive resin composition. When the solvent includes an alcohol having no olefinic double bond, the content of the alcohol having no olefinic double bond in the total solvent is preferably 5 to 50 wt %, and more preferably 10 to 30 wt %. When the content of the alcohol having no olefinic double bond is 5 wt % or more, the storage stability of the photosensitive resin composition is improved, and when it is 50 wt % or less, the solubility of the copolymer resin containing a polyimide and polyimide precursor (A) is improved.

### (D) Silane Coupling Agent

To improve the adhesion of the relief pattern, the photosensitive resin composition can optionally include (D) a silane coupling agent. The silane coupling agent (D) preferably has a structure represented by the following general formula (9):

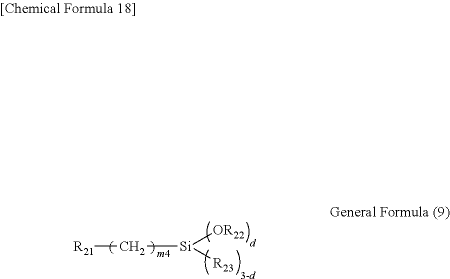

wherein, in formula (9), R₂₁ is at least one selected from the group consisting of substituents including an epoxy group, a phenylamino group and a ureido group, R₂₂ is each independently an alkyl group having 1 to 4 carbon atoms, R₂₃ is a hydroxyl group or an alkyl group having 1 to 4 carbon atoms, d is an integer of 1 to 3, and m₄ is an integer of 1 to 6.

In the general formula (9), d is not limited as long as it is an integer of 1 to 3, but is preferably 2 or 3, and more preferably 3, from the viewpoint of the adhesion to the metal rewiring layer. m₄ is not limited as long as it is an integer of 1 to 6, but is preferably 1 or more and 4 or less from the viewpoint of the adhesion to the metal rewiring layer. From the viewpoint of the developability, it is preferably 2 or more and 5 or less.

R₂₁ is not limited as long as it is a substituent having any one of structures consisting of an epoxy group, a phenylamino group, a ureido group, an isocyanate group and an isocyanuric group. Of these, preferred is at least one selected from the group consisting of a substituent having a phenylamino group and a substituent having a ureido group, from the viewpoint of the developability and adhesion of the metal rewiring layer, and more preferred is a substituent having a phenylamino group. R₂₂ is not limited as long as it is an alkyl group having 1 to 4 carbon atoms. Examples thereof include a methyl group, an ethyl group, a propyl group, an isopropyl group, a butyl group, an isobutyl group, a t-butyl group and the like. R₂₃ is not limited as long as it is a hydroxyl group or an alkyl group having 1 to 4 carbon atoms. Examples of the alkyl group having 1 to 4 carbon atoms include the same alkyl groups as those as for R₂₂.

Examples of the epoxy group-containing silane coupling agent include 2-(3,4-epoxy cyclohexyl)ethyltrimethoxysilane, 3-glycidoxypropylmethyldimethoxysilane, 3-glycidoxypropyltrimethoxysilane, 3-glycidoxypropyltrimethoxysilane, 3-glycidoxypropylmethyldiethoxysilane, 3-glycidoxypropyltriethoxysilane and the like. Examples of the phenylamino group-containing silane coupling agent include N-phenyl-3-aminopropyltrimethoxysilane. Examples of the ureido group-containing silane coupling agent include 3-ureidopropyltrialkoxysilane. Examples of the isocyanate group-containing silane coupling agent include 3-isocyanatopropyltriethoxysilane.

The content of the silane coupling agent (D) in the resin composition is 0.2 wt % to 10 wt %, based on 100 parts by weight of the copolymer resin containing a polyimide and polyimide precursor (A), and is more preferably 1 wt % to 8 wt %, and still more preferably 2 wt % to 6 wt %, from the viewpoint of the copper adhesion.

### (E) Radically Polymerizable Compound

To improve the resolution of the relief pattern and to suppress the cure shrinkage during heat curing, the photosensitive resin composition can optionally include (E) a radically polymerizable compound. Such compound is preferably a (meth)acrylic compound which undergoes a radical polymerization reaction with a photopolymerization initiator, and examples thereof include, but are not particularly limited to, compounds, such as di(meth)acrylate of ethylene glycol or polyethylene glycol, including diethylene glycol dimethacrylate and tetraethylene glycol dimethacrylate, di(meth)acrylate of propylene glycol or polypropylene glycol, di(meth)acrylate or tri(meth)acrylate of glycerol, cyclohexane di(meth)acrylate, di(meth)acrylate of 1,4-butanediol, di(meth)acrylate of 1,6-hexanediol, di(meth)acrylate of neopentyl glycol, di(meth)acrylate of bisphenol A, (meth)acrylamide, derivatives thereof, trimethylolpropane tri(meth)acrylate, di(meth)acrylate or tri(meth)acrylate of glycerol, di(meth)acrylate, tri(meth)acrylate or tetra(meth)acrylate of pentaerythritol, and ethylene oxide or propylene oxide adducts of these compounds. Of these radically polymerizable compounds, it is preferable to have three or more radically polymerizable groups from the viewpoint of suppressing the cure shrinkage. These monomers may be used alone or in a mixture of two or more thereof.

The content of the radically polymerizable compound (E) in the resin composition is 0.5 wt % to 50 wt %, relative to 100 parts by weight of the copolymer containing the polyimide and polyimide precursor (A). From the viewpoints of the resolution and suppression of the cure shrinkage, the content is more preferably 5 wt % to 40 wt %, and still more preferably 10 wt % to 30 wt %.

### (F) Thermal Crosslinking Agent

To suppress the cure shrinkage of the film after curing, the photosensitive resin composition can optionally include (F) a thermal crosslinking agent.

The thermal crosslinking agent (F) means a compound which causes an addition reaction or a condensation polymerization reaction by heat. These reactions occur by combinations of the copolymer resin containing the a polyimide and polyimide precursor (A) and the thermal crosslinking agent (F), the thermal crosslinking agents (F), and the thermal crosslinking agent (F) and other components mentioned later, and the reaction temperature is preferably 150° C. or higher.

Examples of the thermal crosslinking agent (F) include alkoxymethyl compounds, epoxy compounds, oxetane compounds, bismaleimide compounds, allyl compounds and blocked isocyanate compounds. From the viewpoint of suppressing the cure shrinkage, the thermal crosslinking agent (F) preferably contains a nitrogen atom.

Examples of alkoxymethyl compounds include, but are not limited to, the following compounds. [Chemical Formula 19]

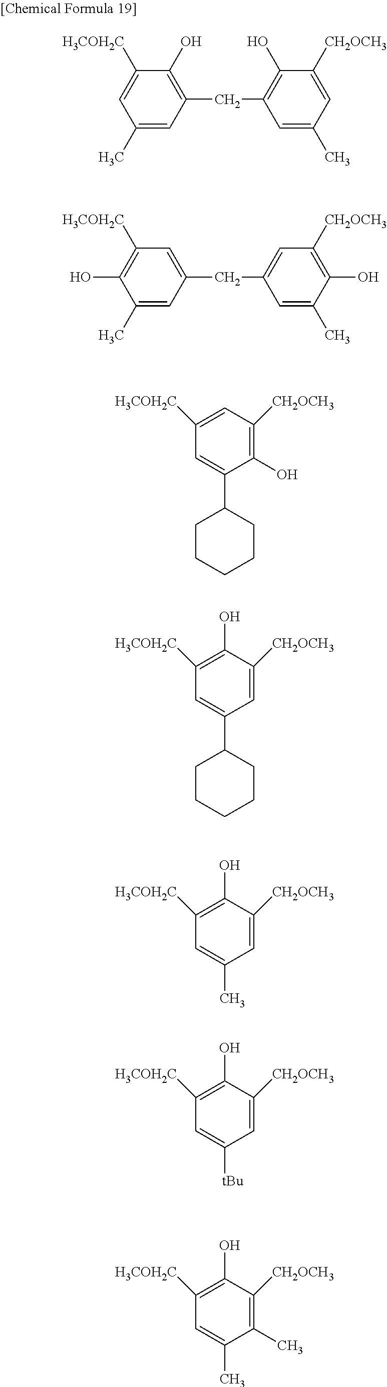

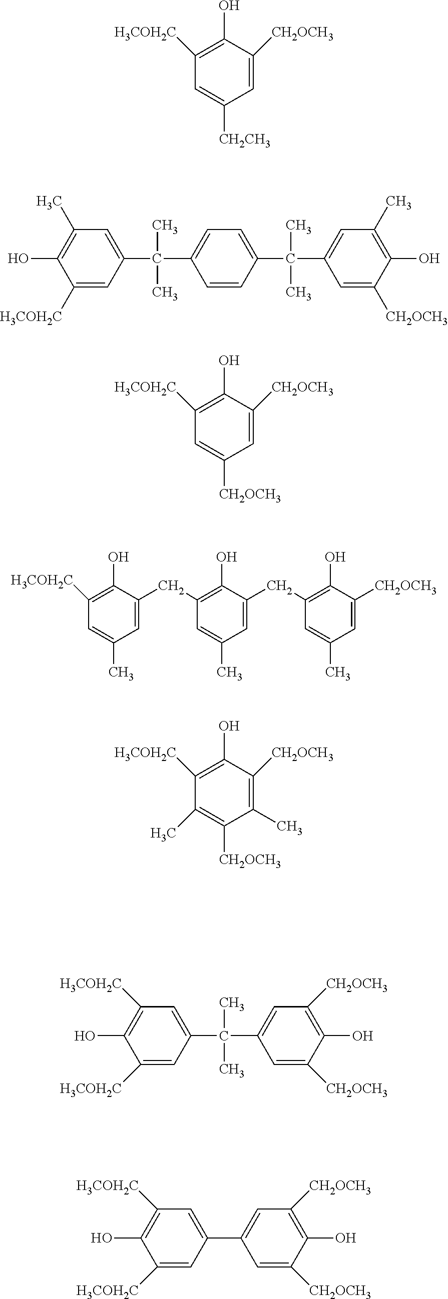

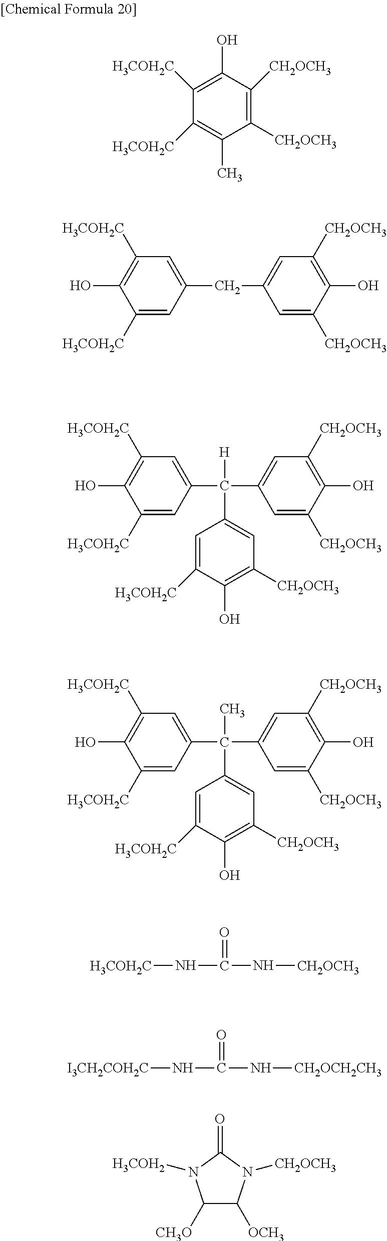

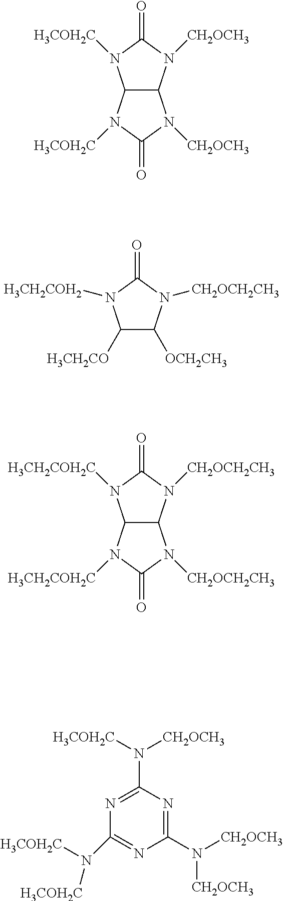

Examples of epoxy compounds include a bisphenol A type group-containing epoxy compound, hydrogenated bisphenol A diglycidyl ether (e.g., Epolite 4000, manufactured by Kyoeisha Chemical Co., Ltd.) and the like. Examples of oxetane compounds include 1,4-bis{[(3-ethyl-3-oxetanyl)methoxy]methyl}benzene, bis[1-ethyl(3-oxetanyl)]methyl ether, 4,4′-bis[(3-ethyl-3-oxetanyl)methyl]biphenyl, 4,4′-bis(3-ethyl-3-oxetanylmethoxy)biphenyl, ethylene glycol bis(3-ethyl-3-oxetanylmethyl)ether, diethylene glycol bis(3-ethyl)-3-oxetanylmethyl)ether, bis(3-ethyl-3-oxetanylmethyl)diphenoate, trimethylolpropane tris(3-ethyl-3-oxetanylmethyl)ether, pentaerythritol tetrakis(3-ethyl-3-oxetanylmethyl) ether, poly [[3-[(3-ethyl-3-oxetanyl)methoxy]propyl]silsesquioxane]derivatives, oxetanyl silicate, phenol novolac type oxetane, 1,3-bis [(3-ethyl oxetan-3-yl)methoxy]benzene, OXT121 (trade name, manufactured by TOAGOSEI CO., LTD.), OXT221 (trade name manufactured by TOAGOSEI CO., LTD.) and the like. Examples of bismaleimide compounds include 1,2-bis(maleimido)ethane, 1,3-bis(maleimido)propane, 1,4-bis(maleimido)butane, 1,5-bis(maleimido)pentane, 1,6-bis(maleimido)hexane, 2,2,4-trimethyl-1,6-bis(maleimido)hexane, N,N′-1,3-phenylenebis(maleimide), 4-methyl-N,N′-1, 3-phenylenebis(maleimide), N,N′-1,4-phenylenebis(maleimide), 3-methyl-N,N′-1,4-phenylenebis(maleimide), 4,4′-bis(maleimide)diphenylmethane, 3,3′-diethyl-5,5′-dimethyl-4,4′-bis(maleimido)diphenylmethane or 2,2-bis[4-(4-maleimidophenoxy)phenyl]propane. Examples of allyl compounds include allyl alcohol, allylanisole, benzoic acid allyl ester, cinnamic acid allyl ester, N-allyloxyphthalimide, allylphenol, allylphenylsulfone, allyl urea, diallyl phthalate, diallyl isophthalate, diallyl terephthalate, diallyl maleate, diallyl isocyanurate, triallylamine, triallyl isocyanurate, triallyl cyanurate, triallylamine, triallyl 1,3,5-benzenetricarboxylate, triallyl trimellitate, triallyl phosphate, triallyl phosphite, triallyl citrate and the like. Examples of blocked isocyanate compounds include hexamethylene diisocyanate-based blocked isocyanates (e.g., DURANATE SBN-70D, SBB-70P, SBF-70E, TPA-B80E, 17B-60P, MF-B60B, E402-B80B, MF-K60B and WM44-L70G manufactured by Asahi Kasei Co., Ltd., Takenate B-882N, Baxenden 7960, 7961, 7982, 7991 and 7992 manufactured by Mitsui Chemicals Inc.), tolylene diisocyanate-based blocked isocyanates (e.g., Takenate B-830, manufactured by Mitsui Chemicals Inc.), 4,4′-diphenylmethane diisocyanate-based blocked isocyanates (e.g., Takenate B-815N, manufactured by Mitsui Chemicals, and Bronate PMD-OA01 and PMD-MA01 manufactured by TAIEI SANGYO CO., LTD.), 1,3-bis(isocyanatomethyl)cyclohexane-based blocked isocyanates (e.g., Takenate B-846N, manufactured by Mitsui Chemicals Inc., Coronate BI-301, 2507 and 2554 manufactured by Tosoh Corporation), and isophorone diisocyanate-based blocked isocyanates (e.g., 7950, 7951 and 7990, manufactured by Baxenden Chemicals Limited). Of these, from the viewpoint of the storage stability, blocked isocyanates and bismaleimide compounds are preferable. The thermal crosslinking agent (F) may be used alone or in combination of two or more thereof.

The content of the thermal crosslinking agent (F) in the resin composition is 0.2 wt % to 40 wt % based on 100 parts by weight of the copolymer containing a polyimide and polyimide precursor (A), and rom the viewpoints of low dielectric properties and suppression of the cure shrinkage, the content is more preferably 1 wt % to 20 wt %, and still more preferably 2 wt % to 10 wt %.

### (G) Filler

To suppress the cure shrinkage of the film after curing, the photosensitive resin composition can optionally include (G) a filler. The filler is not limited as long as it is an inert substance added to improve the strength and various properties.

The filler is preferably particulate from the viewpoint of suppressing an increase in viscosity when the resin composition is prepared. Examples of the particle shape include acicular, plate and spherical shapes. From the viewpoint of suppressing an increase in viscosity when the resin composition is prepared, the filler is preferably spherical.

Examples of the acicular filler include wollastonite, potassium titanate, xonotlite, aluminum borate, acicular calcium carbonate and the like.

Examples of the plate-shaped filler include talc, mica, sericite, glass flake, montmorillonite, boron nitride, plate-shaped calcium carbonate and the like.

Examples of the spherical filler include calcium carbonate, silica, alumina, titanium oxide, clay, hydrotalcite, magnesium hydroxide, zinc oxide, barium titanate and the like. Of these, silica, alumina, titanium oxide and barium titanate are preferable, and silica and alumina are more preferable, from the viewpoint of the electrical properties and storage stability when prepared as a resin composition.

The size of the filler is defined as the primary particle size in the case of a spherical shape, and the length of the long side in the case of a plate or spherical shape, and the size is preferably 5 nm to 1,000 nm, and more preferably 10 nm to 1,000 nm. If the size is 10 nm or more, the resin composition tends to be sufficiently uniform when a resin composition is prepared, and if the size is 1,000 nm or less, the photosensitivity can be imparted. From the viewpoint of imparting the photosensitivity, the size is preferably 800 nm or less, more preferably 600 nm or less, and particularly preferably 300 nm or less. From the viewpoint of the adhesion and uniformity of the resin composition, the size is preferably 15 nm or more, more preferably 30 nm or more, and particularly preferably 50 nm or more.

The content of the filler (G) in the resin composition is 1% by volume to 20% by volume based on 100 parts by weight of the copolymer containing a polyimide and polyimide precursor (A), and from the viewpoint of the dielectric properties, the content is preferably 5% by volume to 20% by volume. From the viewpoint of the resolution, the content is more preferably 5% by volume to 10% by volume.

### (H) Other Components

The photosensitive resin composition may further include components other than the above components (A) to (G). Examples of other components include resin components other than the copolymer containing a polyimide and polyimide precursor (A); organic compounds containing a metal element, sensitizers, thermal polymerization inhibitors, azole compounds and hindered phenol compounds.

The photosensitive resin composition may further include resin components other than the copolymer containing a polyimide and polyimide precursor (A). Examples of resin components which can be included in the photosensitive resin composition include polyimides, polyoxazoles, polyoxazole precursors, phenol resins, polyamides, epoxy resins, siloxane resins, acrylic resins and the like. The amount of these resin components mixed is preferably within a range of 0.01 part by weight to 20 parts by weight relative to 100 parts by weight of the copolymer containing a polyimide and polyimide precursor (A).

The photosensitive resin composition may include an organic compound containing a metal element. The organic compound containing a metal element preferably contains at least one metal element selected from the group consisting of titanium and zirconium in one molecule. It is preferable to contain, as an organic group, a hydrocarbon group and a hydrocarbon group containing a heteroatom. By including an organic compound, the imidization rate of the polyimide precursor included in the photosensitive resin composition increases, leading to a decrease in dielectric loss tangent of the cured film. Examples of the organic titanium or zirconium compounds which can be used include those in which an organic group is bonded to a titanium atom or zirconium atom via a covalent bond or an ionic bond.

### Specific Examples of the Organic Titanium or Zirconium Compound are Shown in I) to VII) Below

I) The chelate compound is more preferably a compound having two or more alkoxy groups because of obtaining the storage stability of the photosensitive resin composition and satisfactory pattern. Specific examples of the chelate compound include, but are not limited to, titanium bis(triethanolamine)diisopropoxide, titanium di(n-butoxide)bis(2,4-pentanedionate), titanium diisopropoxide bis(2,4-pentanedionate), titanium diisopropoxide bis(tetramethylheptanedionate), titanium diisopropoxide bis(ethylacetoacetate), and compounds in which the titanium atom of these compounds is substituted with a zirconium atom.
II) Examples of the tetraalkoxy compound include, but are not limited to, titanium tetra(n-butoxide), titanium tetraethoxide, titanium tetra(2-ethylhexoxide), titanium tetraisobutoxide, titanium tetraisopropoxide, titanium tetramethoxide, titanium tetramethoxypropoxide, titanium tetramethylphenoxide, titanium tetra(n-nonyloxide), titanium tetra(n-propoxide), titanium tetrastearyloxide, titanium tetrakis[bis{2,2-(allyloxymethyl)butoxide}], and compounds in which the titanium atom of these compounds is substituted with a zirconium atom.
III) Examples of the titanocene or zirconocene compound include, but are not limited to, pentamethylcyclopentadienyltitanium trimethoxide, bis(15-2,4-cyclopentadien-1-yl)bis(2,6-difluorophenyl)titanium, bis(g5-2,4-cyclopentadien-1-yl)bis(2,6-difluoro-3-(1H-pyrrol-1-yl)phenyl)titanium, and compounds in which the titanium atom of these compounds is substituted with a zirconium atom.
IV) Examples of the monoalkoxy compound include, but are not limited to, titanium tris(dioctylphosphate)isopropoxide, titanium tris(dodecylbenzenesulfonate)isopropoxide, and compounds in which the titanium atom of these compounds is substituted with a zirconium atom.
V) Examples of the titanium oxide or zirconium oxide compounds include, but are not limited to, titanium oxide bis(pentanedionate), titanium oxide bis(tetramethylheptanedionate), phthalocyanine titanium oxide, and compounds in which the titanium atom of these compounds are substituted with a zirconium atom.
VI) Examples of the titanium tetraacetylacetonate or zirconium tetraacetylacetonate compound include, but are not limited to, titanium tetraacetylacetonate, and compounds in which the titanium atom of these compounds is substituted with a zirconium atom.
VII) Examples of titanate coupling agent include, but are not limited to, isopropyl tridodecylbenzenesulfonyl titanate.

Of the above I) to VII), the organic titanium compound is preferably at least one compound selected from the group consisting of I) titanium chelate compound, II)tetraalkoxytitanium compound and III) titanocene compound from the viewpoint of exhibiting satisfactory dielectric loss tangent. In particular, titanium diisopropoxide bis(ethylacetoacetate), titanium tetra(n-butoxide) and bis(15-2,4-cyclopentadien-1-yl)bis(2,6-difluoro-3-(1H)-pyrrol-1-yl)phenyl)titanium is preferable.

When the organic titanium or zirconium compound is mixed, the mixing amount is 0.01 to 5 parts by weight, and preferably 0.1 to 3 parts by weight, based on the copolymer containing a polyimide and polyimide precursor (A). When the mixing amount is 0.01 part by weight or more, satisfactory imidization ratio of the resin composition and dielectric loss tangent of the cured film are exhibited, and when the amount is 10 parts by weight or less, excellent storage stability is exhibited, which is preferable.

When the photosensitive resin composition includes an organic compound containing a metal element, the imidization rate of the polyimide precursor included in the resin composition can be improved, leading to a decrease in dielectric loss tangent of the cured film using the resin composition. Although not bound by theory, the reason for improving the imidization rate of the polyimide precursor is considered that the metal element contained in the organic compound containing a metal element is coordinated to a carbonyl group derived from an ester group, an amide group and/or a carboxyl group of the polyimide precursor to reduce the electron density of the carbon atom of the carbonyl group, leading to promotion of a ring closure reaction.

The photosensitive resin composition can optionally include a sensitizer to improve the photosensitivity. Examples of the sensitizers include Michler's ketone, 4,4′-bis(diethylamino)benzophenone, 2,5-bis(4′-diethylaminobenzal)cyclopentane, 2,6-bis(4′-diethylaminobenzal)cyclohexanone, 2,6-bis(4′-diethylaminobenzal)-4-methylcyclohexanone, 4,4′-bis(dimethylamino)chalcone, 4,4′-bis(diethylamino)chalcone, p-dimethylamino cinnamylideneindanone, p-dimethylaminobenzylideneindanone, 2-(p-dimethylaminophenylbiphenylene)-benzothiazole, 2-(p-dimethylaminophenylvinylene)benzothiazole, 2-(p-dimethylaminophenylvinylene)isonaphthothiazole, 1,3-bis(4′-dimethylaminobenzal)acetone, 1,3-bis(4′-diethylaminobenzal)acetone, 3,3′-carbonyl-bis(7-diethylaminocoumarin), 3-acetyl-7-dimethylaminocoumarin, 3-ethoxycarbonyl-7-dimethylaminocoumarin, 3-benzyloxycarbonyl-7-dimethylaminocoumarin, 3-methoxycarbonyl-7-diethylaminocoumarin, 3-ethoxycarbonyl-7-diethylaminocoumarin, N-phenyl-N′-ethylethanolamine, N-phenyldiethanolamine, N-p-tolyldiethanolamine, N-phenylethanolamine, 4-morpholinobenzophenone, isoamyl dimethylaminobenzoate, isoamyl diethylaminobenzoate, 2-mercaptobenzimidazole, 1-phenyl-5-mercaptotetrazole, 2-mercaptobenzothiazole, 2-(p-dimethylaminostyryl)benzoxazole, 2-(p-dimethylaminostyryl)benzthiazole, 2-(p-dimethylaminostyryl)naphtho(1,2-d)thiazole, 2-(p-dimethylaminobenzoyl)styrene and the like. These can be used alone or in combination of a plurality (for example, 2 to 5 types) thereof. The mixing amount of the sensitizer is preferably 0.1 to 25 parts by weight relative to 100 parts by weight of the copolymer containing a polyimide and polyimide precursor (A).

The photosensitive resin composition may optionally include a thermal polymerization inhibitor to improve the viscosity and the stability of the photosensitivity of the photosensitive resin composition during storage in a state of a solvent-containing solution. Examples of the thermal polymerization inhibitor include hydroquinone, N-nitrosodiphenylamine, p-tert-butylcatechol, phenothiazine, N-phenylnaphthylamine, ethylenediaminetetraacetic acid, 1,2-cyclohexanediaminetetraacetic acid, glycol etherdiaminetetraacetic acid, 2,6-di-tert-butyl-p-methylphenol, 5-nitroso-8-hydroxyquinoline, 1-nitroso-2-naphthol, 2-nitroso-1-naphthol, 2-nitroso-5-(N-ethyl-N-sulfopropylamino)phenol, N-nitroso-N-phenylhydroxylamine ammonium salt, N-nitroso-N(1-naphthyl)hydroxylamine ammonium salt and the like. These thermal polymerization inhibitors may be used alone or in combination of two or more thereof. The content of the thermal polymerization inhibitor is preferably within a range of 0.005 part by weight to 12 parts by weight relative to 100 parts by weight of the copolymer containing a polyimide and polyimide precursor (A).

The photosensitive resin composition can optionally include an azole compound to suppress discoloration of the substrate when using a substrate made of copper or a copper alloy. Examples of the azole compound include 1H-triazole, 5-methyl-1H-triazole, 5-ethyl-1H-triazole, 4,5-dimethyl-1H-triazole, 5-phenyl-1H-triazole, 4-t-butyl-5-phenyl-1H-triazole, 5-hydroxyphenyl-1H-triazole, phenyltriazole, p-ethoxyphenyltriazole, 5-phenyl-1-(2-dimethylaminoethyl)triazole, 5-benzyl-1H-triazole, hydroxyphenyltriazole, 1,5-dimethyltriazole, 4,5-diethyl-1H-triazole, 1H-benzotriazole, 2-(5-methyl-2-hydroxyphenyl)benzotriazole, 2-[2-hydroxy-3,5-bis(α,α-dimethylbenzyl)phenyl]-benzotriazole, 2-(3,5-di-t-butyl-2-hydroxyphenyl)benzotriazole, 2-(3-t-butyl-5-methyl-2-hydroxyphenyl)-benzotriazole, 2-(3,5-di-t-amyl-2-hydroxyphenyl)benzotriazole, 2-(2′-hydroxy-5′-t-octylphenyl)benzotriazole, hydroxyphenylbenzotriazole, tolyltriazole, 5-methyl-1H-benzotriazole, 4-methyl-1H-benzotriazole, 4-carboxy-1H-benzotriazole, 5-carboxy-1H-benzotriazole, 1H-tetrazole, 5-methyl-1H-tetrazole, 5-phenyl-1H-tetrazole, 5-amino-1H-tetrazole, 1-methyl-1H-tetrazole and the like. In particular, tolyltriazole, 5-methyl-1H-benzotriazole and 4-methyl-1H-benzotriazole are preferable. These azole compounds may be used alone, or used as a mixture of two or more thereof.

The amount of the azole compound mixed is preferably 0.1 part by weight to 20 parts by weight relative to 100 parts by weight of the copolymer containing a polyimide and polyimide precursor (A), and is more preferably 0.5 part by weight to 5 parts by mas from the viewpoint of the photosensitive properties. If the mixing amount of the azole compound relative to 100 parts by weight of the copolymer containing a polyimide and polyimide precursor (A) is 0.1 part by weight or more, when the photosensitive resin composition is formed on copper or a copper alloy, discoloration of the surface of copper or a copper alloy is suppressed, meanwhile, the mixing amount is preferably 20 parts by weight or less because of excellent in photosensitivity.

The photosensitive resin composition may include a hindered phenol compound to suppress discoloration of the substrate when using a substrate made of copper or a copper alloy. Examples of the hindered phenol compounds include, but are not limited to, 2,6-di-t-butyl-4-methylphenol, 2,5-di-t-butyl-hydroquinone, octadecyl-3-(3,5-di-t-butyl-4-hydroxyphenyl)propionate, isooctyl-3-(3,5-di-t-butyl-4-hydroxyphenyl)propionate, 4, 4′-methylenebis(2, 6-di-t-butylphenol), 4,4′-thio-bis(3-methyl-6-t-butylphenol), 4,4′-butylidene-bis(3-methyl-6-t-butylphenol), triethyleneglycol-bis[3-(3-t-butyl-5-methyl-4-hydroxyphenyl)propionate], 1,6-hexanediol-bis[3-(3,5-di-t-butyl-4-hydroxyphenyl)propionate], 2,2-thio-diethylenebis[3-(3,5-di-t-butyl-4-hydroxyphenyl)propionate], N,N′-hexamethylenebis(3,5-di-t-butyl-4-hydroxy-hydrocinnamamide), 2,2′-methylene-bis(4-methyl-6-t-butylphenol), 2,2′-methylene-bis(4-ethyl-6-t-butylphenol), pentaerithrityl-tetrakis[3-(3,5-di-t-butyl-4-hydroxyphenyl)propionate], tris-(3,5-di-t-butyl-4-hydroxybenzyl)-isocyanurate, 1,3,5-trimethyl-2,4,6-tris(3,5-di-t-butyl-4-hydroxybenzyl)benzene, 1,3,5-tris(3-hydroxy-2,6-dimethyl-4-isopropylbenzyl)-1,3,5-triazine-2,4,6-(1H,3H,5H)-trione, 1,3,5-tris(4-t-butyl-3-hydroxy-2,6-dimethylbenzyl)-1,3,5-triazine-2,4,6-(1H,3H,5H)-trione, 1,3,5-tris(4-s-butyl-3-hydroxy-2,6-dimethylbenzyl)-1,3,5-triazine-2,4,6-(1H,3H,5H)-trione, 1,3,5-tris[4-(1-ethylpropyl)-3-hydroxy-2,6-dimethylbenzyl]-1,3,5-triazine-2,4,6-(1H,3H,5H)-trione, 1,3,5-tris[4-triethylmethyl-3-hydroxy-2,6-dimethylbenzyl]-1,3,5-triazine-2,4,6-(1H,3H,5H)-trione, 1,3,5-tris(3-hydroxy-2,6-dimethyl-4-phenylbenzyl)-1,3,5-triazine-2,4,6-(1H,3H,5H)-trione, 1,3,5-tris(4-t-butyl-3-hydroxy-2,5,6-trimethylbenzyl)-1,3,5-triazine-2,4,6-(1H,3H,5H)-trione, 1,3,5-tris(4-t-butyl-5-ethyl-3-hydroxy-2,6-dimethylbenzyl)-1,3,5-triazine-2,4,6-(1H,3H,5H)-trione, 1,3,5-tris(4-t-butyl-6-ethyl-3-hydroxy-2-methylbenzyl)-1,3,5-triazine-2,4,6-(1H,3H,5H)-trione, 1,3,5-tris(4-t-butyl-6-ethyl-3-hydroxy-2,5-dimethylbenzyl)-1,3,5-triazine-2,4,6-(1H,3H,5H)-trione, 1,3,5-tris(4-t-butyl-5,6-diethyl-3-hydroxy-2-methylbenzyl)-1,3,5-triazine-2,4,6-(1H,3H,5H)-trione, 1,3,5-tris(4-t-butyl-3-hydroxy-2-methylbenzyl)-1,3,5-triazine-2,4,6-(1H,3H,5H)-trione, 1,3,5-tris(4-t-butyl-3-hydroxy-2,5-dimethylbenzyl)-1,3,5-triazine-2,4,6-(1H,3H,5H)-trione, 1,3,5-tris(4-t-butyl-5-ethyl-3-hydroxy-2-methylbenzyl)-1,3,5-triazine-2,4,6-(1H,3H,5H)-trione and the like. Of these, 1,3,5-tris(4-t-butyl-3-hydroxy-2,6-dimethylbenzyl)-1,3,5-triazine-2,4,6-(1H,3H,5H)-trione is particularly preferable.

The amount of the hindered phenol compound mixed is preferably 0.1 part by weight to 20 parts by weight relative to 100 parts by weight of the copolymer containing a polyimide and polyimide precursor (A), and is more preferably 0.5 part by weight to 10 parts by weight from the viewpoint of the photosensitive properties. If the amount is 0.1 part by weight or more relative to 100 parts by weight of the copolymer containing a polyimide and polyimide precursor (A) of the hindered phenol compound, for example, when the photosensitive resin composition is formed on copper or a copper alloy, discoloration and corrosion of copper or a copper alloy are prevented, meanwhile, the amount is preferably 20 parts by weight or less, because of excellent in photosensitivity.

### <Polyimide Cured Film and Method for Producing Same>

The present disclosure also provides a method for producing a polyimide cured film, which comprises a step of converting a photosensitive resin composition into polyimide. The method for producing a cured polyimide film of the present disclosure comprises, for example, the following steps (1) to (5):
(1) a step of applying the photosensitive resin composition of the present disclosure on a substrate to form a photosensitive resin layer on the substrate;
(2) a step of heating and drying the photosensitive resin layer thus obtained; (3) a step of exposing the heat-dried photosensitive resin layer;
(4) a step of developing the exposed photosensitive resin layer; and
(5) a step of heat-treating the developed photosensitive resin layer to form a polyimide cured film.

The photosensitive resin composition used in the method for producing a cured film preferably contains 100 parts by weight of a copolymer containing a polyimide and polyimide precursor, 0.5 to 30 parts by weight of a photosensitizing agent, and 100 to 1,000 parts by weight of a solvent. It is more preferable that a photoradical polymerization initiator is contained as the photosensitizing agent, and it is still more preferable that the photosensitive resin composition is of a negative photosensitive resin composition.

Specific steps in the method for producing a cured film can be carried out according to steps (1) to (5) of the method for producing a cured film mentioned above. Typical aspects of each step will be described below.

### (1) Photosensitive Resin Layer Formation Step

In this step, the photosensitive resin composition of the present disclosure is applied on a substrate, and as necessary, it is then dried to form a photosensitive resin layer. It is possible to use, as the coating method, a method conventionally used for coating a photosensitive resin composition, for example, a method of coating with a spin coater, a bar coater, a blade coater, a curtain coater, a screen printer or the like, or a method of spray-coating with a spray coater.

### (2) Heating and Drying Step

As necessary, the photosensitive resin composition film can be heated and dried. It is possible to use, as the drying method, methods such as air drying, heat drying using an oven or a hot plate, and vacuum drying. The coating film is preferably dried under such conditions that imidization of the polyimide precursor moiety of the copolymer (A) (polyamic acid ester) in the photosensitive resin composition does not occur. Specifically, when air drying or heat drying is carried out, drying can be carried out at 20° C. to 140° C. for 1 minute to 1 hour. As mentioned above, a photosensitive resin layer can be formed on the substrate.

### (3) Exposure Step

In this step, the photosensitive resin layer thus formed is exposed. It is possible to use, as the exposure device, for example, a contact aligner, a mirror projection, a stepper and the like. Exposure can be carried out through a patterned photomask or reticle, or carried out directly. Light used for exposure is, for example, an ultraviolet light source or the like.

After exposure, for the purpose of improving the photosensitivity or the like, post exposure bake (PEB) and/or pre-development bake may be carried out at any combination of temperature and time, as necessary. The range of bake conditions is preferably as follows: the temperature is within a range of 40 to 120° C. and the time is within a range of 10 seconds to 240 seconds, but is not limited to the above range as long as it does not interfere with various properties of the negative photosensitive resin composition of the present embodiment.

### (4) Development Step

In this step, the exposed photosensitive resin layer is developed to form a relief pattern. When the photosensitive resin composition is of a negative photosensitive resin composition, the unexposed area of the exposed photosensitive resin layer is removed by development. It is possible to use, as the method of developing a photosensitive resin layer after exposure (irradiation), any method selected from conventionally known method of developing a photoresist, such as a rotary spray method, a paddle method and an immersion method accompanied by an ultrasonic treatment. After development, for the purpose of adjusting the shape of the relief pattern or the like, post-development bake may be carried out at any combination of temperature and time, as necessary. A developing solution used for development is preferably, for example, a good solvent for a negative photosensitive resin composition, or a combination of the good solvent and a poor solvent. Examples of the good solvent include N-methyl-2-pyrrolidone, N-cyclohexyl-2-pyrrolidone, N,N-dimethylacetamide, cyclopentanone, cyclohexanone, γ-butyrolactone, α-acetyl-γ-butyrolactone and the like. Preferred examples of the poor solvent include toluene, xylene, methanol, ethanol, isopropyl alcohol, ethyl lactate, propylene glycol methyl ether acetate and water. When the good solvent and the poor solvent are used as a mixture, it is preferable to adjust the ratio of the poor solvent to the good solvent according to the solubility of the polymer in the negative photosensitive resin composition. It is also possible to use two or more types, for example, several types of solvents in combination. In the step of developing the exposed photosensitive resin layer, it is preferable to carry out coating to development steps to obtain a photosensitive resin layer having a thickness of 10 m to 15 μm.

### (5) Polyimide Cured Film Formation Step

In this step, the relief pattern obtained by the above development is heated to dilute the photosensitive component, and the copolymer (A) is imidized to convert into a cured relief pattern made of polyimide. It is possible to select, as the heat curing method, various methods such as a method using a hot plate, a method using an oven, and a method using a heating oven capable of setting a temperature program. Heating can be carried out, for example, at 160° C. to 400° C. for 30 minutes to 5 hours. It is possible to use, as the atmospheric gas for heat curing, either air, or an inert gas such as nitrogen or argon. A cured relief pattern (cured polyimide film) can be produced in the manner mentioned above.

The method for producing a polyimide cured film of the present disclosure comprises, for example, applying the resin composition on a substrate, and subjecting the substrate to an exposure treatment, a development treatment and then a heat treatment, and the cured film preferably has a dielectric loss tangent within a range of 0.003 to 0.011 as measured at 40 GHz by the perturbation type split cylinder resonator method. The dielectric loss tangent can be measured by the perturbation type split cylinder resonator method shown in Examples below.

The present disclosure also provides a cured polyimide film obtained from the photosensitive resin composition described above. From the viewpoint of the transmission loss due to the dielectric, the cured film preferably has a dielectric loss tangent at a frequency of 40 GHz as measured by a perturbation type split cylinder resonator method of 0.003 to 0.011, and the lower the better. From the viewpoint of multi-layering of the rewiring layer, it is preferable that the cured film has low cure shrinkage, and the residual film ratio after curing is preferably 81% to 93%. The residual film ratio after curing of 81% or more leads to minor distortion of the rewiring layer due to copper wiring during rewiring. For redistribution materials for copper wiring used in high-speed transmission, it is preferable that the quotient (RFA/tanδ₄₀) of the residual film ratio after curing (RFA) and the dielectric loss tangent (tanδ₄₀) is within a certain range, the value of the dielectric loss tangent at 40 GHz satisfies 0.003<tanδ₄₀<0.011, and the residual film ratio after curing satisfies 0.81<RFA<0.93 in terms of a ratio (81%<RFA<93% in terms of %) and satisfies the following formula:

$$85 < RFA ( ratio ) / {δ}_{40} < 175$$

When RFA (ratio)/tanδ₄₀ is within a range of more than 85 and less than 175, a polyimide cured product which is suitable as a starting material for copper wiring used in high-speed transmission can be obtained. RFA (ratio)/tanδ₄₀ is more preferably more than 100 and less than 170.

### <Semiconductor Device>

The present disclosure can also provide a semiconductor device having a cured relief pattern obtained by the method for producing a cured relief pattern mentioned above using the photosensitive resin composition of the present disclosure. Accordingly, there is provided a semiconductor device comprising a base material which is a semiconductor element and a cured relief pattern of polyimide formed on the base material by the above method for producing a cured relief pattern. The present disclosure can also be applied to a method for producing a semiconductor device which uses a semiconductor element as the base material and includes the above method for producing a cured relief pattern as part of the steps. The semiconductor device can be produced by forming the cured relief pattern formed by the above method for producing a cured relief pattern as a surface protective film, an interlayer insulating film, an insulating film for rewiring, a protective film for a flip chip device, or a protective film for a semiconductor device having a bump structure, and combining with a known method for producing a semiconductor device.

The polyimide contained in the cured relief pattern (cured polyimide film) formed from the photosensitive resin composition preferably has a structure represented by the following general formula (10):

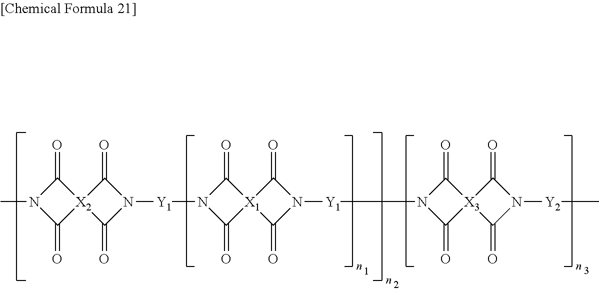

wherein, in General formula (10), X₁, X₂, X₃, Y₁ and Y₂ are the same as X₁, X₂, X₃, Y₁ and Y₂ in the above general formula (1), n₁ is an integer of 2 to 30, and n₂ and n₃ are an integer of 2 to 150.

### <Display Device>

The present disclosure can also provide a display device comprising a display element and a cured film provided on top of the display element using the photosensitive resin composition of the present disclosure, wherein the cured film is the cured relief pattern. Here, the cured relief pattern may be laminated in direct contact with the display element, or may be laminated with another layer interposed therebetween. Examples of the cured film include a surface protective film, an insulating film and a planarizing film for TFT liquid crystal display elements and color filter elements, projections for MVA type liquid crystal display devices, and barrier ribs for cathodes of organic EL devices.

The photosensitive resin composition of the present disclosure is also useful for applications such as interlayer insulation of multilayer circuits, cover coats for flexible copper-clad plates, solder resist films and liquid crystal alignment films, in addition to application to the semiconductor device as mentioned above.

### <Method for Producing Photosensitive Resin Composition>

The method for producing a photosensitive resin composition of the present disclosure includes the steps of. producing (A) a copolymer resin by the method of the present disclosure as described above in “(A) Method for producing a copolymer resin containing a polyimide and polyimide precursor”; and mixing 100 parts by weight of (A) a copolymer resin, 0.5 to 30 parts by weight of (B) a photopolymerization initiator, and (C) 100 to 1,000 parts by weight of a solvent to obtain a photosensitive resin composition. Optionally, the above-described (D) silane coupling agent, (E) a radically polymerizable compound, (F) a thermal crosslinking agent, (G) a filler, and (H) other components may be mixed.

### Examples

Physical properties of the photosensitive resin compositions in Examples, Comparative Examples and Production Examples of the present disclosure were measured and evaluated according to the following methods.

### <Measurement and Evaluation Methods>

### (1) Weight-Average Molecular Weight

The weight-average molecular weight (Mw) of a diamine oligomer and a copolymer resin was measured by gel permeation chromatography (in terms of standard polystyrene). The column used for the measurement was Shodex 805M/806M in series manufactured by Showa Denko K.K., and Shodex STANDARD SM-105 manufactured by Showa Denko K.K. was selected as the standard monodisperse polystyrene, and N-methyl-2-pyrrolidone was used as the developing solvent, and Shodex RI-930 manufactured by Showa Denko K.K. was used as the detector.

### (2) Measurement of Imide Structure Introduction Ratio of Copolymer Resin

A copolymer resin (10 g) was dissolved in a mixed solvent of γ-butyrolactone and DMSO (weight ratio of 90:10), and the amount of the solvent was adjusted so that the viscosity was approximately 25 poise to prepare a polymer solution. The above polymer solution was spin-coated on a 6-inch silicon wafer (manufactured by Fujimi Denshi Kogyo Co., Ltd., thickness of 625±25 m) using a coater developer (Model D-Spin60A, manufactured by SOKUDO), and then heat-dried on a hot plate at 110° C. for 3 minutes to form a photosensitive resin layer having a thickness of about 10 m. The photosensitive resin layer was measured by an ATR-FTIR measurement device (Nicolet Continuum, manufactured by Thermo Fisher Scientific K.K.) using a Si prism in the measurement range of 4,000 cm⁻¹ to 700 cm⁻¹ with 50 measurements. An imidization index 1 was calculated by dividing the peak height of the cured film near 1,380 cm⁻¹ (1,350 cm−¹ to 1,450 cm−; if there are multiple peaks, the peak with the maximum intensity) by the peak height of the cured film near 1,500 cm⁻¹ (1,460 cm⁻¹ to 1550 cm⁻¹; if there are multiple peaks, the peak with the maximum intensity). An imidization index of a film cured separately at 350° C. under the same conditions was divided by 2 to calculate an imide structure introduction ratio.

### (3) Resolution and Developing Time of Cured Relief Pattern on Cu Substrate

Using a sputtering device (Model L-440S-FHL, manufactured by Canon Anelva Corporation), a 200 nm thick Ti layer and a 400 nm thick Cu layer were sputtered in this order on a 6 inch silicon wafer (manufactured by Fujimi Denshi Kogyo Co., Ltd., thickness of 625±25 m). Subsequently, a photosensitive resin composition prepared by the method mentioned below is spin-coated on this wafer using a coater developer (Model D-Spin60A, manufactured by SOKUDO), and then heat-dried on a hot plate at 110° C. for 3 minutes to form a photosensitive resin layer having a thickness of about 13.5 m. This photosensitive resin layer was irradiated with energy of 600 mJ/cm2 from Prisma GHI (manufactured by Ultratech, Inc.) equipped with an i-ray filter using a mask with a test pattern. Next, this photosensitive resin layer was spray-developed with a coater developer (Model D-Spin60A, manufactured by SOKUDO) using cyclopentanone as a developing solution, and rinsed with propylene glycol methyl ether acetate to form a relief on Cu. The spray developing time at this time was defined as the developing time. The wafer on which the relief pattern was formed on Cu was heated in a nitrogen atmosphere at 230° C. for 2 hours using a temperature-rising programmable curing furnace (Model VF-2000, manufactured by Koyo Lindberg Ltd.) to obtain a cured relief pattern made of a resin having a thickness of about 10 m. The relief pattern thus fabricated was observed under an optical microscope to determine the size of a minimum opening pattern. At this time, if the area of the opening of the obtained pattern is ½ or more of the opening area of the corresponding pattern mask, it was regarded as being resolved, and the resolution was judged according to the following evaluation criteria based on the length of the mask opening side corresponding to those having the smallest area of the resolved openings (size of the opening pattern).

### (Evaluation Criteria)

A: The size of the minimum opening pattern was less than 10 m;
B: The size of the minimum opening pattern was 10 m or more and less than 15 m;
C: The size of the minimum opening pattern was 15 m or more and less than 20 m; and
D: The size of the minimum opening pattern was 20 m or more.

### (4) Measurement of Dielectric Properties (Relative Dielectric Constant: Dk, Dielectric Loss Tangent: Df)

Using a sputtering device (Model L-440S-FHL, manufactured by Canon Anelva Corporation), 100 nm thick aluminum (Al) was sputtered on a 6 inch silicon wafer (manufactured by Fujimi Denshi Kogyo Co., Ltd., thickness 625±25 m) to prepare a sputtered AI wafer substrate. A photosensitive resin composition prepared by the method mentioned below was spin-coated on the sputtered AI wafer substrate using a spin coater (Model D-Spin60A, manufactured by SOKUDO), and then heat-dried at 110° C. for 180 seconds to form a photosensitive resin layer having a thickness of about 13.5 m. Then, using an aligner (PLA-501F, manufactured by Canon Inc.), the entire surface was exposed to ghi rays at an exposure dose of 600 mJ/cm2, followed by a heat-curing treatment at 230° C. for 2 hours under a nitrogen atmosphere using a vertical curing furnace (manufactured by Koyo Lindberg Co., Ltd., model name VF-2000B) to fabricate a cured film made of a resin having a thickness of about 10 m on an AI wafer. Using a dicing saw (manufactured by Disco Corporation, model name DAD-2H/6T), this cured film was cut into 80 mm long and 62 mm wide (for 10 GHz measurement) and 40 mm long and 30 mm wide (for measurement at 40 GHz), immersed in an aqueous 10% hydrochloric acid and then stripped from the silicon wafer to obtain a film sample. The relative permittivity (Dk) and dielectric loss tangent (Df) of the film sample as measured at 10 GHz and 40 GHz by the resonator perturbation method. The details of the measurement method are as follows.

### (Measurement Method)

Perturbation type split cylinder resonator method

### (Measurement Sample Humidity Control)

23° C./50% RH, leave to stand for 24 hours

### (Measurement Conditions)

23° C./50% RH

### (Equipment Configuration)

Network analyzer:
PNA Network analyzer N5224B
(manufactured by Keysight Technologies)
Split cylinder resonator:
CR-710 (manufactured by KANTO ELECTRONIC APPLICATION AND DEVELOPMENT, measurement frequency: about 10 GHz)
CR-740 (manufactured by KANTO ELECTRONIC APPLICATION AND DEVELOPMENT, measurement frequency: about 40 GHz)
   (5) Measurement of Residual Film Ratio after Curing

Using a sputtering device (Model L-440S-FHL, manufactured by Canon Anelva Corporation), 200 nm thick Ti and 400 nm thick Cu were sputtered in this order on a 6 inch silicon wafer (manufactured by Fujimi Denshi Kogyo Co., Ltd., thickness of 625±25 m). Subsequently, a photosensitive resin composition prepared by the method mentioned below was spin-coated on this wafer using a coater developer (Model D-Spin60A, manufactured by SOKUDO), and then heat-dried on a hot plate at 110° C. for 3 minutes to form a photosensitive resin layer having a thickness of about 13.5 m. Then, using an aligner (PLA-501F, manufactured by Canon Inc.), the entire surface was exposed to ghi-ray at an exposure dose of 800 mJ/cm2. Thereafter, the coating film formed on the wafer was spray-developed with cyclopentanone by a developer (Model D-SPIN636, manufactured by Dainippon Screen Mfg. Co., Ltd., Japan). After rinsing with propylene glycol methyl ether acetate, drying was carried out by spin drying. This film thickness after development was measured and taken as a film thickness 1. This developed film was further subjected to a heat-curing treatment at 230° C. for 2 hours under a nitrogen atmosphere using a vertical curing furnace (manufactured by Koyo Lindberg Co., Ltd., model name VF-2000B). The film thickness after this heat treatment was measured and taken as a film thickness 2. Using these film thicknesses, the residual film ratio after curing (ratio and %) was calculated according to the following formulas.

Residual film ratio after curing(ratio)=film thickness2/film thickness1

Residual film ratio after curing (%)=film thickness2/film thickness1×100

The quotient (RFA (ratio)/tanδ₄₀) of the residual film ratio after curing (ratio) and the dielectric loss tangent (tanδ₄₀) was calculated.

### (6) Evaluation of Copper Adhesion

Using a sputtering device (Model L-440S-FHL, manufactured by Canon Anelva Corporation), 200 nm thick Ti and 400 nm thick Cu were sputtered in this order on a 6 inch silicon wafer (manufactured by Fujimi Denshi Kogyo Co., Ltd., thickness of 625±25 m). Subsequently, a photosensitive resin composition prepared by the method mentioned below was spin-coated on this wafer using a coater developer (Model D-Spin60A, manufactured by SOKUDO), and then heat-dried on a hot plate at 110° C. for 3 minutes to form a photosensitive resin layer having a thickness of about 13.5 m. Then, using an aligner (PLA-501F, manufactured by Canon Inc.), the entire surface was exposed to ghi-ray at an exposure dose of 800 mJ/cm2, followed by subjecting to a heat-curing treatment at 230° C. for 2 hours under a nitrogen atmosphere using a vertical curing furnace (manufactured by Koyo Lindberg Co., Ltd., model name VF-2000B) to fabricate a cured film made of a resin having a thickness of about 10 μm on a Cu wafer. In accordance with JIS K 5600-5-6 standard cross-cut method, the adhesive properties between the copper substrate and the cured resin coating film of the heat-treated film were evaluated by the following criteria.

### (Evaluation Criteria)

A: Those in which the number of grids of the cured resin coating film adhered to the substrate is 80 or more to 100.
B: Those in which the number of grids of the cured resin coating film adhered to the substrate is 60 or more to less than 80.
C: Those in which the number of grids of the cured resin coating film adhered to the substrate is 40 or more to less than 60.
D: Those in which the number of grids of the cured resin coating film adhered to the substrate is less than 40.

In this disclosure, the results above B are considered to be preferable.

### (7) Storage Stability

A photosensitive resin composition mentioned below was prepared and left to stand at room temperature for 24 hours, and then the viscosity was measured at 23° C. by an E-type viscometer (VISCOMATE VM-150111, manufactured by TOKI SANGYO). This initial viscosity was taken as viscosity 1. After the measurement, the photosensitive resin composition was stored at 40° C. for 3 days, and the viscosity was measured again under the same conditions. The viscosity after this heat treatment was taken as viscosity 2. Using these viscosities, the storage stability was calculated according to the following formula.

$$Viscosity change ratio ( \% ) = ( \vert viscosity 2 - viscosity 1 \vert / viscosity 1 ) \times 100$$

### (Evaluation Criteria)

A: Viscosity change ratio is less than 3%.
B: Viscosity change ratio is 3% or more and less than 5%.
C: Viscosity change ratio is 5% or more and less than 10%.
D: Viscosity change ratio is 10% or more.

In this disclosure, the results above C are considered to be preferable.

### <Production of Diamine X-1>

A 5 L four-necked flask was purged with Ar, and 172.02 g of 4,4′-butylindenebis(6-tert-butyl-m-cresol), 155.84 g of 4-chloronitrobenzene, 1.5 L of DMF were charged therein, followed by stirring. After adding 186.42 g of K₂ CO₃ thereto and heating at 150° C. for 5 hours, disappearance of starting materials and intermediates was confirmed by TLC. After cooling to room temperature, the reaction solution was filtered and the filtrate was concentrated under reduced pressure at 80° C. The concentrated residue was poured into 1.6 L of ion-exchanged water and 2.5 L of ethyl acetate was further added, followed by separation and purification three times. The organic layer was collected and dried over MgSO4. After drying, impurities were removed by filtration and the residue was dissolved by adding 800 mL of toluene, followed by the addition of the solution to 4.0 L of methanol and further stirring for 30 minutes. After stirring, the residue was collected by filtration and dried at 80° C. for 12 hours. The reaction product obtained by drying was charged in a 5 L four-necked flask purged with Ar, and 19.04 g of 5% Pd/C (EA) and 1.9 L of THF were added, followed by stirring. The flask was heated to 40° C. and H2 bubbling (10 mL/min) was carried out, and then a reduction reaction was carried out for 24 hours. The reaction solution was filtered through celite, and the target fraction was collected by silica gel chromatography and then concentrated under reduced pressure to obtain a diamine X-1.

### <(A) Production of Diamine Compound Including Repeating Unit of Polyimide Structure>

### Synthesis of Polyimide (Diamine Oligomer W-1)

In a 0.5 liter separable flask equipped with a Dean-Stark tube and a cooling tube, 41.6 g of 4,4′-(4,4′-isopropylidenediphenoxy)diphthalic anhydride (BPADA) as an acid component, 34.0 g of 2,2′-dimethylbiphenyl-4,4′-diamine (m-TB) as a diamine component, and 176.4 g of N-methylpyrrolidone (NMP) as a solvent were charged and then dissolved while stirring. Further, 42.3 g of toluene was added and, after stirring, the temperature was raised to 185° C. under a nitrogen atmosphere. After stirring at 185° C. for 2.5 hours, toluene in the system and water produced by imidization were removed over 1.5 hours. After cooling to room temperature, a solution of a diamine oligomer W-1 including a repeating unit of a polyimide structure was obtained. The weight-average molecular weight (Mw) of this diamine oligomer W-1 was measured and found to be 3,000. ¹H-NMR measurement of the diamine oligomer W-1 was carried out, and the imide ring closure ratio was confirmed by comparing the peaks derived from amide bonds with the peaks derived from aromatic rings of the polyimide. The imide ring closure ratio was 99% or more.

### Synthesis of Polyimide (Diamine Oligomer W-2)

In the same manner as in the method mentioned in the synthesis method of the diamine oligomer W-1, except that 52.6 g of 2,2-bis[4-(4-aminophenoxy)-3-methylphenyl]propane (MBAPP) was used in place of 34.0 g of m-TB, and 220 g of NMP and 52.8 g of toluene were used as solvents in the synthesis method of the diamine oligomer W-1, a reaction was carried out to obtain a solution of a diamine oligomer W-2. The weight-average molecular weight (Mw) of this diamine oligomer W-2 was measured and found to be 5,000. As with diamine oligomer W-1, the imide ring closure ratio obtained by H-NMR measurement was 99% or more.

### Synthesis of Polyimide (Diamine Oligomer W-3)

In the same manner as in the method mentioned in the synthesis method of the diamine oligomer W-1, except that 24.8 g of 4,4′-oxydiphthalic dianhydride (ODPA) was used in place of 41.6 g of BPADA, 65.7 g of 2,2-bis[4-(4-aminophenoxy)phenyl]propane (BAPP) was used in place of 34.0 g of m-TB, and 211 g of NMP and 50.7 g of toluene were used as solvents in the synthesis method of the diamine oligomer W-1, a reaction was carried out to obtain a solution of a diamine oligomer W-3. The weight-average molecular weight (Mw) of this diamine oligomer W-3 was measured and found to be 2,700. As with diamine oligomer W-1, the imide ring closure rate obtained by H-NMR measurement was 99% or more.

### Synthesis of Polyimide (Diamine Oligomer W-4)

In the same manner as in the method mentioned in the synthesis method of the diamine oligomer W-1, except that 24.8 g of ODPA was used in place of 41.6 g of BPADA, 70.2 g of MBAPP was used in place of 34.0 g of m-TB, and 222 g of NMP and 53.0 g of toluene were used as solvents in the synthesis method of the diamine oligomer W-1, a reaction was carried out to obtain a solution of a diamine oligomer W-4. The weight-average molecular weight (Mw) of this diamine oligomer W-4 was measured and found to be 3,000. As with diamine oligomer W-1, the imide ring closure rate obtained by H-NMR measurement was 99% or more.

### Synthesis of Polyimide (Diamine Oligomer W-5)

In the same manner as in the method mentioned in the synthesis method of the diamine oligomer W-1, except that 24.8 g of ODPA was used in place of 41.6 g of BPADA, 90.4 g of a diamine X-1 was used in place of 34.0 g of m-TB, and 269 g of NMP and 64.5 g of toluene were used as solvents in the synthesis method of the diamine oligomer W-1, a reaction was carried out to obtain a solution of a diamine oligomer W-5. The weight-average molecular weight (Mw) of this diamine oligomer W-5 was measured and found to be 3,500. As with diamine oligomer W-1, the imide ring closure rate obtained by H-NMR measurement was 99% or more.

### Synthesis of Polyimide (Diamine Oligomer W-6)

In the same manner as in the method mentioned in the synthesis method of the diamine oligomer W-1, except that 55.8 g of 9,9-bis(4-aminophenyl)fluorene (BAFL) was used in place of 34.0 g of m-TB, and 188 g of NMP and 45.1 g of toluene were used as solvents in the synthesis method of the diamine oligomer W-1, a reaction was carried out to obtain a solution of a diamine oligomer W-6. The weight-average molecular weight (Mw) of this diamine oligomer W-6 was measured and found to be 2,900. As with diamine oligomer W-1, the imide ring closure rate obtained by H-NMR measurement was 99% or more.

### Synthesis of Polyimide (Diamine Oligomer W-7)

In the same manner as in the method mentioned in the synthesis method of the diamine oligomer W-1, except that 37.2 g of BAFL was used in place of 34.0 g of m-TB, and 145 g of NMP and 34.7 g of toluene were used as solvents in the synthesis method of the diamine oligomer W-1, a reaction was carried out to obtain a solution of a diamine oligomer W-7. The weight-average molecular weight (Mw) of this diamine oligomer W-7 was measured and found to be 8,200. As with diamine oligomer W-1, the imide ring closure rate obtained by 1 H-NMR measurement was 99% or more.

### Synthesis of Polyimide (Diamine Oligomer W-8)

In the same manner as in the method mentioned in the synthesis method of the diamine oligomer W-1, except that 24.8 g of ODPA was used in place of 41.6 g of BPADA, 51.2 g of 4,4′-diamino-2,2′-bis(trifluoromethyl)biphenyl (TFMB) was used in place of 34.0 g of m-TB, and 177 g of NMP and 42.6 g of toluene were used as solvents in the synthesis method of the diamine oligomer W-1, a reaction was carried out to obtain a solution of a diamine oligomer W-8. The weight-average molecular weight (Mw) of this diamine oligomer W-8 was measured and found to be 2,500. As with diamine oligomer W-1, the imide ring closure rate obtained by 1 H-NMR measurement was 99% or more.

### Synthesis of Polyimide (Diamine Oligomer W-9)

In the same manner as in the method mentioned in the synthesis method of the diamine oligomer W-1, except that 35.5.8 g of 4,4′-(hexafluoroisopropylidene)diphthalic anhydride (6FDA) was used in place of 41.6 g of BPADA, 65.7 g of 2,2-bis[4-(4-aminophenoxy)phenyl]propane (BAPP) was used in place of 34.0 g of m-TB, and 236 g of NMP and 56.7 g of toluene were used as solvents in the synthesis method of the diamine oligomer W-1, a reaction was carried out to obtain a solution of a diamine oligomer W-9. The weight-average molecular weight (Mw) of this diamine oligomer W-9 was measured and found to be 3,200. As with diamine oligomer W-1, the imide ring closure rate obtained by H-NMR measurement was 99% or more.

### Synthesis of Polyimide (Diamine Oligomer W-10)

In the same manner as in the method mentioned in the synthesis method of the diamine oligomer W-1, except that 20.7 g of 1,10-diaminodecane was used in place of 34.0 g of m-TB, and 249 g of NMP and 34.9 g of toluene were used as solvents in the synthesis method of the diamine oligomer W-1, a reaction was carried out to obtain a solution of a diamine oligomer W-10. The weight-average molecular weight (Mw) of this diamine oligomer W-10 was measured and found to be 3,700. As with diamine oligomer W-1, the imide ring closure rate obtained by 1 H-NMR measurement was 99% or more.

### (A) Production of Copolymer Resin containing Polyimide and Polyimide Precursor

### Synthesis of Polymer A-1

In a 1-liter separable flask, 20.9 g of BPADA as an acid component was charged, and 10.9 g of 2-hydroxyethyl methacrylate (HEMA) and 42 g of γ-butyrolactone (GBL) were added. While stirring at room temperature, 6.4 g of pyridine was added and the mixture was heated at 50° C. for 4 hours and, after completion of heat generation due to the reaction, the mixture was allowed to cool to room temperature. A reaction mixture was obtained by being left to stand for additional 16 hours.

Next, under ice cooling, a solution prepared by dissolving 16.3 g of dicyclohexylcarbodiimide (DCC) in 16.3 g of GBL was added to the reaction mixture over 40 minutes while stirring, and then 91.0 g of GBL was added. Subsequently, a solution prepared by mixing 101.7 g of the NMP solution of the diamine oligomer W-2 prepared above with 66.5 g of GBL as a diamine component was added over 20 minutes while stirring. Further, a solution prepared by dissolving 2.4 g of m-TB in 7 g of GBL was added thereto over 5 minutes while stirring. After stirring at room temperature for additional 4 hours, 6.4 g of ethyl alcohol was added and, after stirring for 30 minutes, 49.0 g of GBL was added. The precipitate formed in the reaction mixture was removed by filtration to obtain a reaction solution.

The reaction solution thus obtained was added to 1,000 g of ethyl alcohol to produce a precipitate made of a crude polymer. The crude polymer thus produced was collected by filtration and dissolved in 270 g of γ-butyrolactone to obtain a crude polymer solution. The crude polymer solution thus obtained was purified using an anion exchange resin (“AmberlystT M 15JWET”, manufactured by Organo Corporation) to obtain a polymer solution. The polymer solution thus obtained was added dropwise to 3,800 g of water to precipitate a polymer, and the precipitate thus obtained was collected by filtration and dried in vacuum to obtain a powdered polymer A-1. The weight-average molecular weight (Mw) of this polymer A-1 was 30,000 and the imide group introduction ratio was 0.43. The polyimide obtained from the polymer A-1 had an imide group concentration U per repeating unit of 16.0% by weight. The “imide group concentration U” is calculated by converting it into polyimide of a polyimide cured film obtained by heating and curing at 350° C. (the same applies hereinafter).

### Synthesis of Polymer A-2

In a 1-liter separable flask, 15.2 g of BPADA as an acid component was charged, and 7.9 g of HEMA and 30.8 g of γ-butyrolactone (GBL) were added. While stirring at room temperature, 4.6 g of pyridine was added, and the mixture was heated at 50° C. for 4 hours and, after completion of heat generation due to the reaction, the mixture was allowed to cool to room temperature. A reaction mixture was obtained by being left to stand for additional 16 hours.

Next, under ice cooling, a solution prepared by dissolving 11.9 g of dicyclohexylcarbodiimide (DCC) in 11.9 g of GBL was added to the reaction mixture over 40 minutes while stirring, and then 91.0 g of GBL was added. Subsequently, a solution prepared by mixing 111.5 g of the NMP solution of the diamine oligomer W-1 prepared above with 72.5 g of GBL as a diamine component was added over 20 minutes while stirring. After stirring at room temperature for additional 4 hours, 49.0 g of GBL was added. The precipitate formed in the reaction mixture was removed by filtration to obtain a reaction solution.

The subsequent purification step was carried out in the same manner as in the method mentioned in the synthesis method of the polymer A-1 to obtain a polymer A-2. This polymer A-2 had a weight-average molecular weight (Mw) of 24,000 and an imide group introduction ratio of 0.58. The polyimide obtained from the polymer A-2 had an imide group concentration U per repeating unit of 20.1% by weight.

### Synthesis of Polymer A-3

In a 1-liter separable flask, 15.2 g of BPADA as an acid component was charged, and 7.9 g of HEMA (first substituent-introduced compound) and 30.8 g of GBL were added. While stirring at room temperature, 4.6 g of pyridine was added and the mixture was heated at 50° C. for 4 hours and, after completion of heat generation due to the reaction, the mixture was allowed to cool to room temperature. A reaction mixture was obtained by being left to stand for additional 16 hours (first reaction).

In a separately prepared 0.5 L three-neck flask, 111.5 g of an NMP solution of the diamine oligomer W-1 as a diamine component was mixed with 72.9 g of GBL and, while stirring under ice cooling, 3.1 g of 2-isocyanatoethyl methacrylate (second substituent-introduced compound) was dissolved in 15.5 g of GBL, followed by stirring for 1 hour under ice cooling to obtain a reaction mixture solution with the diamine oligomer W-1 (second reaction).

In parallel with the second reaction, a solution prepared by dissolving 11.9 g of DCC in 20 g of GBL was added to the reaction mixture of the first reaction under ice cooling over 40 minutes while stirring. Subsequently, the reaction mixture solution of the diamine oligomer W-1 obtained in the second reaction as a diamine component was added over 60 minutes while stirring. After stirring at room temperature for additional 4 hours, 49.0 g of GBL was added. The precipitate formed in the reaction mixture was removed by filtration to obtain a reaction solution.

The subsequent purification step was carried out in the same manner as in the method mentioned in the synthesis method of the polymer A-1 to obtain a polymer A-3. This polymer A-3 had a weight-average molecular weight (Mw) of 18,000 and an imide group introduction ratio of 0.58. The polyimide obtained from the polymer A-3 had an imide group concentration U per repeating unit of 20.1% by weight.

### Synthesis of Polymer A-4

In the same manner as in the method mentioned in the synthesis method of the polymer A-1, except that 17.0 g of BPADA was used in place of 20.9 g of BPADA, 8.8 g of HEMA was used in place of 10.9 g of HEMA, 13.3 g of DCC was used in place of 16.3 g of DCC, and 127.2 g of an NMP solution of a diamine oligomer W-2 was used in place of 101.7 g of the NMP solution of the diamine oligomer W-2 and 2.4 g of mTB in the synthesis method of the polymer A-1, a reaction was carried out to obtain a polymer A-3. This polymer A-3 had a weight-average molecular weight (Mw) of 35,000 and an imide group introduction ratio of 0.53. The polyimide obtained from the polymer A-4 had an imide group concentration U per repeating unit of 15.2% by weight.

### Synthesis of Polymer A-5

In the same manner as in the method mentioned in the synthesis method of the polymer A-2, except that 8.1 g of ODPA was used in place of 15.2 g of BPADA, 7.1 g of HEMA was used in place of 7.9 g of HEMA, 10.7 g of DCC was used in place of 11.9 g of DCC, and 169.6 g of an NMP solution of a diamine oligomer W-3 was used in place of 111.5 g of the NMP solution of the diamine oligomer W-3 in the synthesis method of the polymer A-2, a reaction was carried out to obtain a polymer A-5. This polymer A-5 had a weight-average molecular weight (Mw) of 22,000 and an imide group introduction ratio of 0.63. The polyimide obtained from the polymer A-4 had an imide group concentration U per repeating unit of 20.5% by weight.

### Synthesis of Polymer A-6

In the same manner as in the method mentioned in the synthesis method of the polymer A-2, except that 8.1 g of ODPA was used in place of 15.2 g of BPADA, 7.1 g of HEMA was used in place of 7.9 g of HEMA, 10.7 g of DCC was used in place of 11.9 g of DCC, and 176.7 g of an NMP solution of a diamine oligomer W-4 was used in place of 111.5 g of the NMP solution of the diamine oligomer W-1 in the synthesis method of the polymer A-2, a reaction was carried out to obtain a polymer A-6. This polymer A-6 had a weight-average molecular weight (Mw) of 23,000 and an imide group introduction ratio of 0.63. The polyimide obtained from the polymer A-6 had an imide group concentration U per repeating unit of 19.6% by weight.

### Synthesis of Polymer A-7

In the same manner as in the method mentioned in the synthesis method of the polymer A-1, except that 12.4 g of ODPA was used in place of 20.9 g of BPADA, and 143.1 g of an NMP solution of a diamine oligomer W-5 was used in place of 101.7 g of the NMP solution of the diamine oligomer W-2 and 2.4 g of m-TB in the synthesis method of the polymer A-1, a reaction was carried out to obtain a polymer A-7. This polymer A-7 had a weight-average molecular weight (Mw) of 21,000 and an imide group introduction ratio of 0.43. The polyimide obtained from the polymer A-7 had an imide group concentration U per repeating unit of 16.7% by weight.

### Synthesis of Polymer A-8

In a 1-liter separable flask, 12.4 g of ODPA as an acid component was charged, and 10.8 g of HEMA (first substituent-introduced compound) and 26.0 g of GBL were added. While stirring at room temperature, 6.3 g of pyridine was added to obtain a reaction mixture (first reaction). After completion of heat generation due to the reaction, the mixture was allowed to cool to room temperature and then left to stand for additional 16 hours.

Next, under ice cooling, a solution prepared by dissolving 16.3 g of dicyclohexylcarbodiimide (DCC) in 16.3 g of GBL was added to the reaction mixture of the first reaction over 40 minutes while stirring. Subsequently, 1.1 g of allylamine (second substituent-introduced compound) was dissolved in 5.5 g of GBL, and the GBL solution was added thereto over 5 minutes while stirring (second reaction). To the reaction mixture of the second reaction, a solution prepared by dissolving 143.1 g of the NMP solution of the diamine oligomer W-5 in 93.6 g of GBL as a diamine component was added over 60 minutes while stirring. After stirring at room temperature for additional 4 hours, 6.4 g of ethyl alcohol was added and, after stirring for 30 minutes, 49.0 g of GBL was added. The precipitate formed in the reaction mixture was removed by filtration to obtain a reaction solution.

The subsequent purification step was carried out in the same manner as in the method mentioned in the synthesis method of the polymer A-1, a reaction was carried out to obtain a polymer A-8. This polymer A-8 had a weight-average molecular weight (Mw) of 19,000 and an imide group introduction ratio of 0.43. The polyimide obtained from the polymer A-8 had an imide group concentration U per repeating unit of 16.7% by weight.

### Synthesis of Polymer A-9

In the same manner as in the method mentioned in the synthesis method of the polymer A-1, except that 105.6 g of an NMP solution of a diamine oligomer W-6 was used in place of 101.7 g of the NMP solution of the diamine oligomer W-2 and 2.4 g of m-TB in the synthesis method of the polymer A-1, a reaction was carried out to obtain a polymer A-9. This polymer A-9 had a weight-average molecular weight (Mw) of 29,000 and an imide group introduction ratio of 0.43. The polyimide obtained from the polymer A-9 had an imide group concentration U per repeating unit of 16.8% by weight.

### Synthesis of Polymer A-10

In the same manner as in the method mentioned in the synthesis method of the polymer A-2, except that 4.6 g of BPADA was used in place of 15.2 g of BPADA, 2.4 g of HEMA was used in place of 7.9 g of HEMA, 3.6 g of DCC was used in place of 11.9 g of DCC, and 174.4 g of an NMP solution of a diamine oligomer W-7 was used in place of 111.5 g of the NMP solution of the diamine oligomer W-1 in the synthesis method of the polymer A-2, a reaction was carried out to obtain a polymer A-10. This polymer A-10 had a weight-average molecular weight (Mw) of 40,000 and an imide group introduction ratio of 0.88. The polyimide obtained from the polymer A-10 had an imide group concentration U per repeating unit of 16.8% by weight.

### Synthesis of Polymer A-11

In the same manner as in the method mentioned in the synthesis method of the polymer A-3, except that 4.6 g of BPADA was used in place of 15.2 g of BPADA, 2.4 g of HEMA was used in place of 7.9 g of HEMA, 3.6 g of DCC was used in place of 11.9 g of DCC, 174.4 g of an NMP solution of a diamine oligomer W-7 was used in place of 111.5 g of the NMP solution of the diamine oligomer W-1, and 2.1 g of methacrylic acid chloride and 1.4 g of pyridine were used in place of 3.1 g of 2-isocyanatoethyl methacrylate in the synthesis method of the polymer A-3, a reaction was carried out to obtain a polymer A-11. This polymer A-I1 had a weight-average molecular weight (Mw) of 36,000 and an imide group introduction ratio of 0.88. The polyimide obtained from the polymer A-I1 had an imide group concentration U per repeating unit of 16.8% by weight.

### Synthesis of Polymer A-12

In the same manner as in the method mentioned in the synthesis method of the polymer A-1, except that 12.1 g of ODPA was used in place of 20.9 g of BPADA, and 85.5 g of an NMP solution of a diamine oligomer W-8 was used in place of 101.7 g of the NMP solution of the diamine oligomer W-2 and 2.4 g of m-TB in the synthesis method of the polymer A-1, a reaction was carried out to obtain a polymer A-12. This polymer A-12 had a weight-average molecular weight (Mw) of 26,000 and an imide group introduction ratio of 0.58. The polyimide obtained from the polymer A-12 had an imide group concentration U per repeating unit of 23.6% by weight.

### Synthesis of Polymer A-13

In the same manner as in the method mentioned in the synthesis method of the polymer A-1, except that 17.3 g of 6FDA was used in place of 20.9 g of BPADA, and 113.8 g of an NMP solution of a diamine oligomer W-9 were used in place of 101.7 g of the NMP solution of the diamine oligomer W-2 and 2.4 g of m-TB in the synthesis method of the polymer A-1, a reaction was carried out to obtain a polymer A-13. This polymer A-13 had a weight-average molecular weight (Mw) of 28,000 and an imide group introduction ratio of 0.44. The polyimide obtained from the polymer A-13 had an imide group concentration U per repeating unit of 17.1% by weight.

### Synthesis of Polymer A-14

In the same manner as in the method mentioned in the synthesis method of the polymer A-2, except that 7.7 g of 3,3′,4,4′-biphenyltetracarboxylic dianhydride (BPDA) was used in place of 15.2 g of BPADA, 7.1 g of HEMA was used in place of 7.9 g of HEMA, 10.7 g of DCC was used in place of 11.9 g of DCC, and 150.1 g of an NMP solution of a diamine oligomer W-4 was used in place of 111.5 g of the NMP solution of the diamine oligomer W-1 in the synthesis method of the polymer A-2, a reaction was carried out to obtain a polymer A-14. This polymer A-14 had a weight-average molecular weight (Mw) of 21,000 and an imide group introduction ratio of 0.63. The polyimide obtained from the polymer A-14 had an imide group concentration U per repeating unit of 19.8% by weight.

### Synthesis of Polymer A-15

In the same manner as in the method mentioned in the synthesis method of the polymer A-1, except that 30.6 g of BPADA was used in place of 20.9 g of BPADA, 15.9 g of HEMA was used in place of 10.9 g of HEMA, 9.3 g of pyridine was used in place of 6.4 g of pyridine, 23.9 g of DCC was used in place of 16.3 g of DCC, and 45.0 g of an NMP solution of a diamine oligomer W-6 and 14.7 g of MBAPP were used in place of 101.7 g of the NMP solution of the diamine oligomer W-2 and 2.4 g of m-TB in the synthesis method of the polymer A-1, a reaction was carried out to obtain a polymer A-15. This polymer A-15 had a weight-average molecular weight (Mw) of 28,000 and an imide group introduction ratio of 0.16. The polyimide obtained from the polymer A-15 had an imide group concentration U per repeating unit of 15.8% by weight.

### Synthesis of Polymer A-16

In the same manner as in the method mentioned in the synthesis method of the polymer A-1, except that 20.2 g of BPADA was used in place of 20.9 g of BPADA, 10.5 g of HEMA was used in place of 10.9 g of HEMA, 15.8 g of DCC was used in place of 16.3 g of DCC, and 70 g of an NMP solution of a diamine oligomer W-10 was used in place of 101.7 g of the NMP solution of the diamine oligomer W-2 in the synthesis method of the polymer A-1, a reaction was carried out to obtain a polymer A-16. This polymer A-16 had a weight-average molecular weight (Mw) of 26,000 and an imide group introduction ratio of 0.44. The polyimide obtained from the polymer A-16 had an imide group concentration U per repeating unit of 21.1% by weight.

### Synthesis of Polymer A-17

In the same manner as in the method mentioned in the synthesis method of the polymer A-2, except that 13.9 g of glycerol dimethacrylate was used in place of 7.9 g of HEMA in the synthesis method of the polymer A-2, a reaction was carried out to obtain a polymer A-17. This polymer A-17 had a weight-average molecular weight (Mw) of 24,000 and an imide group introduction ratio of 0.58. The polyimide obtained from the polymer A-17 had an imide group concentration U per repeating unit of 20.10% by weight.

### Synthesis of Polymer A-18

In the same manner as in the method mentioned in the synthesis method of the polymer A-2, except that 7.8 g of 2-aminoethyl methacrylate was used in place of 7.9 g of HEMA in the synthesis method of the polymer A-2, a reaction was carried out to obtain a polymer A-18. This polymer A-18 had a weight-average molecular weight (Mw) of 24,000 and an imide group introduction ratio of 0.58. The polyimide obtained from the polymer A-18 had an imide group concentration U per repeating unit of 20.10% by weight.

### Synthesis of Polymer A-19

In the same manner as in the method mentioned in the synthesis method of the polymer A-2, except that 7.7 g of 2-hydroxybutyl methacrylate (HBMA) and 0.7 g of allyl alcohol were used in place of 7.9 g of HEMA in the synthesis method of the polymer A-2, a reaction was carried out to obtain a polymer A-19. This polymer A-19 had a weight-average molecular weight (Mw) of 24,000 and an imide group introduction ratio of 0.58. The polyimide obtained from the polymer A-19 had an imide group concentration U per repeating unit of 20.1% by weight.

### Synthesis of Polyimide Precursor (Polymer A-20)

In a 1-liter separable flask, 60.2 g of ODPA as an acid component was charged, and 54.2 g of HEMA and 137.5 g of GBL were added. While stirring at room temperature, 31.6 g of pyridine was added to obtain a reaction mixture. After completion of heat generation due to the reaction, the mixture was allowed to cool to room temperature and left to stand for additional 16 hours.

Next, under ice cooling, a solution prepared by dissolving 81.3 g of DCC in 81.3 g of GBL was added to the reaction mixture over 40 minutes while stirring. Further, a solution prepared by dissolving 36.4 g of m-TB in 109.2 g of GBL as a diamine component was added over 60 minutes while stirring. After stirring at room temperature for additional 2.5 hours, 15 g of ethyl alcohol was added and, after stirring for 30 minutes, 150 g of γ-butyrolactone was added, followed by stirring at 50° C. for 0.5 hour. The precipitate formed in the reaction mixture was removed by filtration to obtain a reaction solution.

The reaction solution thus obtained was added to 2,700 g of ethyl alcohol to produce a precipitate made of a crude polymer. The crude polymer thus produced was collected by filtration and dissolved in 1,000 g of γ-butyrolactone to obtain a crude polymer solution. The crude polymer solution thus obtained was purified using an anion exchange resin (“Amberlyst™ 15”, manufactured by Organo Corporation) to obtain a polymer solution. The polymer solution thus obtained was added dropwise to 8,000 g of water to precipitate a polymer, and the precipitate thus obtained was collected by filtration and dried in vacuum to obtain a powdered polymer A-20. The weight-average molecular weight (Mw) of this polymer A-20 was 19,000 and the imide group introduction ratio was 0. The polyimide obtained from the polymer A-20 had an imide group concentration U per repeating unit of 28.8% by weight.

### Synthesis of Polyimide Precursor (Polymer A-21)

In the same manner as in the method mentioned in the synthesis method of the polymer A-20, except that 63.3 g of BAPP was used in place of 36.4 g of m-TB in the synthesis method of the polymer A-20, a reaction was carried out to obtain a polymer A-21. This polymer A-21 had a weight-average molecular weight (Mw) of 21,000 and an imide group introduction ratio of 0. The polyimide obtained from the polymer A-21 had an imide group concentration U per repeating unit of 20.5% by weight.

### Synthesis of Polyimide Precursor (Polymer A-22)

In the same manner as in the method mentioned in the synthesis method of the polymer A-20, except that 58.8 g of BPDA was used in place of 62.0 g of ODPA, and 34.3 g of 4,4′-diaminodiphenyl ether (DADPE) was used in place of 36.4 g of m-TB in the synthesis method of the polymer A-20, a reaction was carried out to obtain a polymer A-22. This polymer A-22 had a weight-average molecular weight (Mw) of 22,000 and an imide group introduction ratio of 0. The polyimide obtained from the polymer A-22 had an imide group concentration U per repeating unit of 30.5% by weight.

### Synthesis of Polyimide Precursor (Polymer A-23)

In the same manner as in the method mentioned in the synthesis method of the polymer A-20, except that 81.3 g of BAPP was used in place of 36.4 g of m-TB in the synthesis method of polymer A-20, a reaction was carried out to obtain a polymer A-23. This polymer A-23 had a weight-average molecular weight (Mw) of 16,000 and an imide group introduction ratio of 0. The polyimide obtained from the polymer A-23 had an imide group concentration U per repeating unit of 20.5% by weight.

### Synthesis of Polyimide (Polymer A-24)

In a 1 liter separable flask equipped with a Dean-Stark tube and a cooling tube, 97.7 g of 6FDA as an acid component, 64.1 g of TFMB as a diamine component, and 529.2 g of N-methylpyrrolidone (NMP) as a solvent were added and dissolved while stirring. Further, 126.9 g of toluene was added and, after stirring, the temperature was raised to 185° C. under a nitrogen atmosphere. After stirring at 185° C. for 2.5 hours, toluene in the system and water produced by imidization were removed over 1.5 hours. After cooling to room temperature, a polyimide solution was obtained.

The polyimide solution thus obtained was added to 1,000 g of methyl alcohol to produce a precipitate made of a crude polymer. The crude polymer thus obtained was collected by filtration and washed again with methyl alcohol. The washed polymer was dried in vacuum at 50° C. to obtain a powdered polymer A-24. The weight-average molecular weight (Mw) of this polymer A-24 was 25,000. H-NMR measurement of the polymer A-24 was carried out, and the imide ring closure ratio was confirmed by comparing the peaks derived from amide bonds with the peaks derived from aromatic rings of the polyimide. The imide ring closure ratio was 99% or more. The polyimide obtained from the polymer A-24 had an imide group concentration U per repeating unit of 19.2% by weight.

### [Components (B) to (G)]

Photopolymerization initiator B1: 3-Cyclopentyl-1-[9-ethyl-6-(2-methylbenzoyl)-9H-carbazol-3-yl]propanone-1-(O-acetyl oxime) (trade name: PBG-304, manufactured by Changzhou Tronly New Electronic Materials Co., Ltd.)
Photopolymerization initiator B2: 1,2-Propanedione-3-cyclopentyl-1-[4-(phenylthio)phenyl]-2-(O-benzoyl oxime) (trade name: PBG-305, manufactured by Changzhou Tronly New Electronic Materials Co., Ltd.)
Photopolymerization initiator B3: 1-[4-(phenylthio)phenyl]-3-propane-1,2-dione-2-(O-acetyl oxime) (trade name: PBG-3057, manufactured by Changzhou Tronly New Electronic Materials Co., Ltd.)
Solvent C1: γ-Butyrolactone
Solvent C2: Dimethyl sulfoxide (DMSO)
Silane coupling agent D-1: 3-Glycidoxypropyltrimethoxysilane (Shin-Etsu Chemical Co., Ltd.)
Silane coupling agent D-2: N-phenyl-3-aminopropyltrimethoxysilane (manufactured by Shin-Etsu Chemical Co., Ltd.)
Silane coupling agent D-3: (3-Triethoxysilylpropyl)-tert-butylcarbamate
Silane Coupling agent D-4: Ureidopropyltriethoxysilane (manufactured by Shin-Etsu Chemical Co., Ltd.)
Silane coupling agent D-5: X-12-1214A (trade name, manufactured by Shin-Etsu Chemical Co., Ltd.)
Silane coupling agent D-6: Tris(-trimethoxysilylpropyl) isocyanurate (manufactured by Shin-Etsu Chemical Co., Ltd.)
Radically polymerizable compound E-1: 1,6-Hexanediol dimethacrylate (manufactured by SHIN-NAKAMURA CHEMICAL CO., LTD.)
Radically polymerizable compound E-2: Pentaerythritol tetraacrylate (manufactured by SHIN-NAKAMURA CHEMICAL CO., LTD.)
Radically polymerizable compound E-3: (PO-modified)trimethylolpropane triacrylate (manufactured by SHIN-NAKAMURA CHEMICAL CO., LTD.)
Radically polymerizable compound E-4: Dipentaerythritol hexaacrylate (manufactured by SHIN-NAKAMURA CHEMICAL CO., LTD.)
Thermal crosslinking agent F-1: Bismaleimide compound (BMI-5100, manufactured by Daiwa Kasei Industry Co., Ltd.)
Thermal crosslinking agent F-2: Block isocyanate (SBB70P, manufactured by Asahi Kasei Corporation)
Thermal crosslinking agent F-3: Alkoxymethyl compound of the following structure (CROLIN-318, manufactured by DAITO CHEMIX Co., Ltd.)

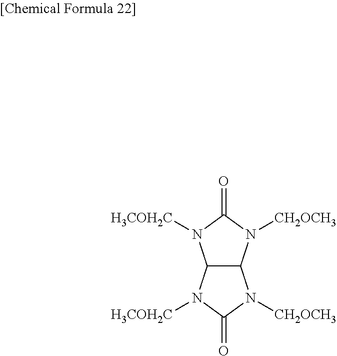

Filler G-1: Spherical silica (K180SP-CY1, manufactured by ADMATECHS CO., LTD.)

### Example 1

As shown in Table 3, 100 g of a polymer A-1 as a component (A) and 7 g of a photopolymerization initiator B-1 as a component (B) were dissolved in a mixed solvent (weight ratio of 90:10) of γ-butyrolactone and DMSO as a solvent (C) to prepare a photosensitive resin composition solution. This composition was evaluated by the above-mentioned method.

### Examples 2 to 37, Comparative Examples 1 to 9

In the same manner as in Example 1, except that the types and amounts of the components were adjusted to the ratios shown in Tables 3 to 6, photosensitive resin compositions were prepared and then evaluated. Only in Comparative Example 8, the prepared photosensitive resin composition solution was left to stand at 40° C. for 240 hours. Using the photosensitive resin composition after being left to stand, the imidization ratio of the photosensitive resin composition layer was measured by the above-mentioned method for measuring the imide structure introduction ratio and was found to be 0.45. The characteristics and evaluation results are shown in Tables 7 to 10.

TABLE 1

| | | | a/b | | |
|---|---|---|---|---|---|
| Diamine | | | (molar | Terminal | |
| oligomer | a: Acid | b: Amine | ratio) | monomer | Mw |
| W-1 | BPADA | m-TB | 1/2 | Amine | 3,000 |
| W-2 | BPADA | MBAPP | 2/3 | Amine | 5,000 |
| W-3 | ODPA | BAPP | 1/2 | Amine | 2,700 |
| W-4 | ODPA | MBAPP | 1/2 | Amine | 3,000 |
| W-5 | ODPA | X-1 | 1/2 | Amine | 3,500 |
| W-6 | BPADA | BAFL | 1/2 | Amine | 2,900 |
| W-7 | BPADA | BAFL | 3/4 | Amine | 8,200 |
| W-8 | ODPA | TFMB | 1/2 | Amine | 2,500 |
| W-9 | 6FDA | BAPP | 1/2 | Amine | 3,200 |
| W-10 | BPADA | 1,10-Diaminodecane | 2/3 | Amine | 3,700 |

TABLE 2

| | | | | | | | Imide | Photo- | Terminal | | |
|---|---|---|---|---|---|---|---|---|---|---|---|
| | | | | | | Imide | group | sensitive | modifier | | |
| | | | | | | structure | concen- | group (first | (second | Terminal | |
| | | | A/B | | | intro- | tration | substituent- | substituent- | photo- | |
| (A) | A: | B: | (molar | Terminal | | duction | U (% by | introduced | introduced | sensitive | Terminal |
| Copolymer | Acid | Amine | ratio) | monomer | Mw | ratio | weight) | compound) | compound) | group | structure |
| A-1 | BPADA | m-TB | 5/4 | Acid | 30,000 | 0.43 | 16.0 | HEMA | — | — | — |
| | | W-2 | | | | | | | | | |
| A-2 | BPADA | W-1 | 6/7 | Amine | 24,000 | 0.58 | 20.1 | HEMA | — | — | — |
| A-3 | BPADA | W-1 | 6/7 | Amine | 18,000 | 0.58 | 20.1 | HEMA | 2- | Methacrylic | Urea |
| | | | | | | | | | Isocyanatoethyl | group | bond |
| | | | | | | | | | methacrylate | | |
| A-4 | BPADA | W-2 | 5/4 | Acid | 35,000 | 0.53 | 15.2 | HEMA | — | — | — |
| A-5 | ODPA | W-3 | 4/5 | Amine | 22,000 | 0.63 | 20.5 | HEMA | — | — | — |
| A-6 | ODPA | W-4 | 4/5 | Amine | 23,000 | 0.63 | 19.6 | HEMA | — | — | — |
| A-7 | ODPA | W-5 | 7/6 | Acid | 21,000 | 0.43 | 16.7 | HEMA | — | — | — |
| A-8 | ODPA | W-5 | 7/6 | Acid | 19,000 | 0.43 | 16.7 | HEMA | Allylamine | Allyl group | Imide |
| | | | | | | | | | | | bond |
| A-9 | BPADA | W-6 | 7/6 | Acid | 29,000 | 0.43 | 16.8 | HEMA | — | — | — |
| A-10 | BPADA | W-7 | 6/7 | amine | 40,000 | 0.88 | 16.8 | HEMA | — | — | — |
| A-11 | BPADA | W-7 | 6/7 | Amine | 36,000 | 0.88 | 16.8 | HEMA | Methacrylic | Methacrylic | Amide |
| | | | | | | | | | acid chloride | group | bond |
| A-12 | ODPA | W-8 | 9/8 | Acid | 26,000 | 0.58 | 23.6 | HEMA | — | — | — |
| A-13 | 6FDA | W-9 | 9/8 | Acid | 28,000 | 0.44 | 17.1 | HEMA | — | — | — |
| A-14 | BPDA | W-4 | 4/5 | Amine | 21,000 | 0.63 | 19.8 | HEMA | — | — | — |
| A-15 | BPADA | MBAPP | 5/4 | Acid | 28,000 | 0.16 | 15.8 | HEMA | — | — | — |
| | | W-6 | | | | | | | | | |
| A-16 | BPADA | m-TB | 6/5 | Acid | 26,000 | 0.44 | 21.1 | HEMA | — | — | — |
| | | W-10 | | | | | | | | | |
| A-17 | BPADA | W-1 | 6/7 | Amine | 24,000 | 0.58 | 20.1 | Glycerol | — | — | — |
| | | | | | | | | dimethacrylate | | | |
| A-18 | BPADA | W-1 | 6/7 | Amine | 24,000 | 0.58 | 20.1 | 2-Aminoethyl | — | — | — |
| | | | | | | | | methacrylate | | | |
| A-19 | BPADA | W-1 | 6/7 | Amine | 24,000 | 0.58 | 20.1 | HBMA | — | — | — |
| | | | | | | | | allyl alcohol | | | |
| A-20 | ODPA | m-TB | 7/6 | Acid | 19,000 | 0 | 28.8 | HEMA | — | — | — |
| A-21 | ODPA | BAPP | 7/6 | Acid | 21,000 | 0 | 20.5 | HEMA | — | — | — |
| A-22 | BPDA | DADPE | 7/6 | Acid | 22,000 | 0 | 30.5 | HEMA | — | — | — |
| A-23 | ODPA | BAPP | 6/7 | Amine | 16,000 | 0 | 20.5 | HEMA | — | — | — |
| A-24 | 6FDA | TFMB | 11/10 | Acid | 25,000 | 1 | 19.2 | — | — | — | — |

TABLE 3

| | | Example 1 | Example 2 | Example 3 | Example 4 | Example 5 | Example 6 |
|---|---|---|---|---|---|---|---|
| (A) Polyimide | A-1 | 100 | | | | 100 | |
| precursor (g) | A-2 | | 100 | | 100 | | 100 |
| | A-3 | | | 100 | | | |
| | A-4 | | | | | | |
| | A-5 | | | | | | |
| | A-6 | | | | | | |
| | A-7 | | | | | | |
| (B) Photopolymerization | B-1 | 7 | | | | | |
| initiator (g) | B-2 | | 7 | | | | |
| | B-3 | | | 7 | 7 | 6 | 7 |
| (C) Solvent (g) | C-1 | 270 | 324 | 324 | 324 | 270 | 324 |
| | C-2 | 30 | 36 | 36 | 36 | 30 | 36 |
| (D) Adhesion aid (g) | D-1 | | | | 2 | 2 | 2 |
| (E) Radical polymerizable | E-1 | | | | | 10 | 10 |
| compound (g) | | | | | | | |

| | | | | | | |
|---|---|---|---|---|---|---|
| Resolution | C | B | B | B | A | A |
| Dk (10 GHz) | 2.9 | 2.9 | 2.9 | 2.9 | 2.9 | 2.9 |
| Df (10 GHz) | 0.0047 | 0.0046 | 0.0047 | 0.0045 | 0.0054 | 0.0053 |
| Dk (40 GHz) | 2.9 | 2.9 | 2.9 | 2.9 | 2.9 | 2.9 |
| Df (40 GHz) | 0.0055 | 0.0054 | 0.0056 | 0.0053 | 0.0064 | 0.0062 |
| Residual film ratio after | 84 | 81 | 83 | 81 | 88 | 86 |
| curing: RFA (%) | | | | | | |
| Copper adhesion | A | A | A | A | A | A |
| Storage stability | A | A | A | A | A | A |
| RFA/tanδ40 | 153.0 | 148.9 | 149.1 | 151.6 | 138.4 | 139.5 |

| | | Example 7 | Example 8 | Example 9 | Example 10 | Example 11 |
|---|---|---|---|---|---|---|
| (A) Polyimide | A-1 | | | | | |
| precursor (g) | A-2 | | | | | |
| | A-3 | 100 | | | | |
| | A-4 | | 100 | | | |
| | A-5 | | | 100 | | |
| | A-6 | | | | 100 | |
| | A-7 | | | | | 100 |
| (B) Photopolymerization | B-1 | | | | | |
| initiator (g) | B-2 | | | | | |
| | B-3 | 7 | 7 | 8 | 8 | 7 |
| (C) Solvent (g) | C-1 | 324 | 324 | 324 | 324 | 270 |
| | C-2 | 36 | 36 | 36 | 36 | 30 |
| (D) Adhesion aid (g) | D-1 | 2 | 2 | 2 | 2 | 2 |
| (E) Radical polymerizable | E-1 | 10 | 10 | 10 | 10 | 10 |
| compound (g) | | | | | | |

| | | | | | |
|---|---|---|---|---|---|
| Resolution | A | C | B | A | B |
| Dk (10 GHz) | 2.9 | 2.9 | 3.0 | 2.9 | 3.1 |
| Df (10 GHz) | 0.0055 | 0.0049 | 0.0090 | 0.0054 | 0.0071 |
| Dk (40 GHz) | 2.9 | 2.9 | 3.0 | 2.9 | 3.1 |
| Df (40 GHz) | 0.0064 | 0.0058 | 0.0098 | 0.0063 | 0.0080 |
| Residual film ratio after | 87 | 90 | 87 | 88 | 88 |
| curing: RFA (%) | | | | | |
| Copper adhesion | A | A | A | A | A |
| Storage stability | A | A | A | A | B |
| RFA/tanδ40 | 136.7 | 155.7 | 89.2 | 139.9 | 110.3 |

TABLE 4

| | | Example 12 | Example 13 | Example 14 | Example 15 | Example 16 | Example 17 |
|---|---|---|---|---|---|---|---|
| (A) Polyimide | A-8 | 100 | | | | | |
| precursor (g) | A-9 | | 100 | | | | |
| | A-10 | | | 100 | | | |
| | A-11 | | | | 100 | | |
| | A-12 | | | | | 100 | |
| | A-13 | | | | | | 100 |
| | A-14 | | | | | | |
| | A-15 | | | | | | |
| | A-16 | | | | | | |
| | A-17 | | | | | | |
| | A-18 | | | | | | |
| | A-19 | | | | | | |
| (B) Photopolymerization | B-3 | 7 | 7 | 10 | 10 | 7 | 7 |
| initiator (g) | | | | | | | |
| (C) Solvent (g) | C-1 | 270 | 324 | 360 | 360 | 324 | 324 |
| | C-2 | 30 | 36 | 40 | 40 | 36 | 36 |
| | C-3 | | | | | | |
| (D) Adhesion aid (g) | D-1 | 2 | 2 | 2 | 2 | 2 | 2 |
| (E) Radically polymerizable | E-1 | 10 | 10 | 10 | 10 | 10 | 10 |
| compound (g) | E-2 | | | | | | |

| | | | | | | |
|---|---|---|---|---|---|---|
| Resolution | B | B | C | C | B | B |
| Dk (10 GHz) | 3.0 | 2.9 | 2.9 | 2.9 | 2.8 | 2.7 |
| Df (10 GHz) | 0.0069 | 0.0090 | 0.0080 | 0.0083 | 0.0084 | 0.0087 |
| Dk (40 GHz) | 3.0 | 2.9 | 2.9 | 2.9 | 2.8 | 2.7 |
| Df (40 GHz) | 0.0078 | 0.0104 | 0.0092 | 0.0096 | 0.0099 | 0.0102 |
| Residual film ratio after | 87 | 89 | 92 | 93 | 85 | 87 |
| curing: RFA (%) | | | | | | |
| Copper adhesion | A | B | A | A | A | A |
| Storage stability | B | B | B | B | B | B |
| RFA/tanδ40 | 112.1 | 85.9 | 99.5 | 97.3 | 86.3 | 85.5 |

| | | Example 18 | Example 19 | Example 20 | Example 21 | Example 22 |
|---|---|---|---|---|---|---|
| (A) Polyimide | A-8 | | | | | |
| precursor (g) | A-9 | | | | | |
| | A-10 | | | | | |
| | A-11 | | | | | |
| | A-12 | | | | | |
| | A-13 | | | | | |
| | A-14 | 100 | | | | |
| | A-15 | | 100 | | | |
| | A-16 | | | 100 | | |
| | A-17 | | | | 100 | |
| | A-18 | | | | | 100 |
| | A-19 | | | | | |
| (B) Photopolymerization | B-3 | 8 | 3 | 7 | 6 | 7 |
| initiator (g) | | | | | | |
| (C) Solvent (g) | C-1 | 324 | 270 | | 324 | |
| | C-2 | 36 | 30 | | 36 | |
| | C-3 | | | 480 | | 360 |
| (D) Adhesion aid (g) | D-1 | 2 | 2 | 2 | 2 | 2 |
| (E) Radically polymerizable | E-1 | 10 | 10 | 10 | 10 | 10 |
| compound (g) | E-2 | | | | | |

| | | | | | |
|---|---|---|---|---|---|
| Resolution | A | A | A | A | A |
| Dk (10 GHz) | 3.1 | 2.9 | 2.8 | 2.9 | 2.9 |
| Df (10 GHz) | 0.0055 | 0.0065 | 0.0052 | 0.0052 | 0.0052 |
| Dk (40 GHz) | 3.1 | 2.9 | 2.8 | 2.9 | 2.9 |
| Df (40 GHz) | 0.0064 | 0.0076 | 0.0052 | 0.0052 | 0.0052 |
| Residual film ratio after | 87 | 90 | 87 | 88 | 87 |
| curing: RFA (%) | | | | | |
| Copper adhesion | A | A | A | A | A |
| Storage stability | B | B | A | A | A |
| RFA/tanδ40 | 136.5 | 117.8 | 117.8 | 117.8 | 117.8 |

TABLE 5

| | | Example | Example | Example | Example | Example | Example | Example | Example |
|---|---|---|---|---|---|---|---|---|---|
| | | 23 | 24 | 25 | 26 | 27 | 28 | 29 | 30 |
| (A) Polyimide | A-1 | | 100 | 100 | 100 | 100 | 100 | 100 | 100 |
| precursor (g) | A-19 | 100 | | | | | | | |
| (B) | B-1 | | 5 | | | | | | |
| Photopolymerization | B-2 | | | 5 | | | | | |
| initiator (g) | B-3 | 8 | | | 5 | 5 | 5 | 5 | 5 |
| (C) Solvent (g) | C-1 | | 324 | 324 | 324 | 324 | 324 | 324 | 324 |
| | C-2 | | 36 | 36 | 36 | 36 | 36 | 36 | 36 |
| | C-3 | 360 | | | | | | | |
| (D) Adhesion aid (g) | D-1 | 2 | 2 | 2 | 2 | 2 | | | |
| | D-2 | | | | | | 2 | | |
| | D-3 | | | | | | | 2 | |
| | D-4 | | | | | | | | 2 |
| | D-5 | | | | | | | | |
| | D-6 | | | | | | | | |
| (E) Radically | E-1 | | 10 | 10 | | | | | |
| polymerizable | E-2 | 10 | | | 10 | | 10 | 10 | 10 |
| compound (g) | E-3 | | | | | 10 | | | |
| (F) Thermal | F-1 | | | | | | | | |
| crosslinking agent (g) | F-2 | | | | | | | | |
| | F-3 | | | | | | | | |
| (G) Filler (g) | G-1 | | | | | | | | |

| | | | | | | | | |
|---|---|---|---|---|---|---|---|---|
| Resolution | B | A | A | A | A | A | A | A |
| Dk (10 GHz) | 2.9 | 2.9 | 2.9 | 2.9 | 2.9 | 2.9 | 2.9 | 2.9 |
| Df (10 GHz) | 0.0059 | 0.0053 | 0.0053 | 0.0064 | 0.0072 | 0.0064 | 0.0064 | 0.0064 |
| Dk (40 GHz) | 2.9 | 2.9 | 2.9 | 2.9 | 2.9 | 2.9 | 2.9 | 2.9 |
| Df (40 GHz) | 0.0059 | 0.0062 | 0.0062 | 0.0074 | 0.0083 | 0.0074 | 0.0074 | 0.0074 |
| Residual film ratio after | 85 | 85 | 86 | 88 | 88 | 88 | 87 | 87 |
| curing: RFA (%) | | | | | | | | |
| Copper adhesion | A | A | A | B | B | A | A | A |
| Storage stability | A | A | A | A | A | A | A | B |
| RFA/tanδ40 | 117.8 | 137.9 | 139.5 | 119.0 | 105.8 | 119.0 | 117.6 | 117.6 |

| | | Example | Example | Example | Example | Example | Example | Example |
|---|---|---|---|---|---|---|---|---|
| | | 31 | 32 | 33 | 34 | 35 | 36 | 37 |
| (A) Polyimide | A-1 | 100 | 100 | 100 | 100 | 100 | 100 | 100 |
| precursor (g) | A-19 | | | | | | | |
| (B) | B-1 | | | | | | | |
| Photopolymerization | B-2 | | | | | | | |
| initiator (g) | B-3 | 5 | 5 | 5 | 5 | 5 | 5 | 5 |
| (C) Solvent (g) | C-1 | 324 | 324 | 324 | 324 | 324 | 324 | 324 |
| | C-2 | 36 | 36 | 36 | 36 | 36 | 36 | 36 |
| | C-3 | | | | | | | |
| (D) Adhesion aid (g) | D-1 | | | 2 | 2 | 2 | 2 | 2 |
| | D-2 | | | | | | | |
| | D-3 | | | | | | | |
| | D-4 | | | | | | | |
| | D-5 | 2 | | | | | | |
| | D-6 | | 2 | | | | | |
| (E) Radically | E-1 | | | | | | | |
| polymerizable | E-2 | 10 | 10 | 10 | 10 | | 10 | 10 |
| compound (g) | E-3 | | | | | | | |
| (F) Thermal | F-1 | | | 10 | | | | |
| crosslinking agent (g) | F-2 | | | | 10 | 10 | | 10 |
| | F-3 | | | | | | 5 | |
| (G) Filler (g) | G-1 | | | | | | | 5 |

| | | | | | | | |
|---|---|---|---|---|---|---|---|
| Resolution | A | A | A | A | A | A | C |
| Dk (10 GHz) | 2.9 | 2.9 | 2.9 | 2.9 | 2.9 | 2.9 | 2.9 |
| Df (10 GHz) | 0.0064 | 0.0069 | 0.0075 | 0.0048 | 0.0051 | 0.0072 | 0.0045 |
| Dk (40 GHz) | 2.9 | 2.9 | 2.9 | 2.9 | 2.9 | 2.9 | 2.9 |
| Df (40 GHz) | 0.0074 | 0.0080 | 0.0086 | 0.0055 | 0.0059 | 0.0081 | 0.0052 |
| Residual film ratio after | 87 | 88 | 91 | 89 | 84 | 89 | 91 |
| curing: RFA (%) | | | | | | | |
| Copper adhesion | A | B | B | B | A | B | B |
| Storage stability | A | B | A | A | A | A | C |
| RFA/tanδ40 | 117.6 | 109.8 | 105.5 | 160.4 | 143.4 | 117.8 | 173.7 |

TABLE 6

| | | Compar- | Compar- | Compar- | Compar- | Compar- | Compar- | Compar- | Compar- | Compar- |
|---|---|---|---|---|---|---|---|---|---|---|
| | | ative | ative | ative | ative | ative | ative | ative | ative | ative |
| | | Example | Example | Example | Example | Example | Example | Example | Example | Example |
| | | 1 | 2 | 3 | 4 | 5 | 6 | 7 | 8 | 9 |
| (A) Polyimide | A-20 | 100 | | | | | | | | |
| precursor (g) | A-21 | | 100 | | | 100 | 100 | 50 | 100 | |
| | A-22 | | | 100 | | | | | | |
| | A-23 | | | | 100 | | | | | |
| | A-24 | | | | | | | 50 | | 100 |
| (B) Photopoly- | B-1 | 5 | 5 | 5 | 5 | 5 | 5 | 5 | 5 | |
| merization | | | | | | | | | | |
| initiator (g) | | | | | | | | | | |
| (C) Solvent (g) | C-1 | 180 | 180 | 180 | 180 | 180 | 180 | 324 | 324 | 324 |
| | C-2 | 20 | 20 | 20 | 20 | 20 | 20 | 36 | 36 | 36 |
| (D) Adhesion | D-1 | 2 | 2 | 2 | 2 | 2 | 2 | 2 | | 2 |
| aid (g) | | | | | | | | | | |
| (E) Radically | E-1 | 10 | 10 | 10 | 10 | | | 10 | | |
| polymerizable | E-2 | | | | | 10 | 10 | | | |
| compound (g) | E-4 | | | | | | | | | 80 |
| (F) Thermal | F-2 | | | | | 10 | | | | |
| crosslinking | | | | | | | | | | |
| agent (g) | | | | | | | | | | |

| | | | | | | | | | |
|---|---|---|---|---|---|---|---|---|---|
| Resolution | A | A | D | C | A | A | — | D | C |
| Dk (10 GHz) | 3.1 | 3.0 | 3.2 | 3.0 | 3.0 | 3.0 | 2.9 | 3.0 | 2.6 |
| Df (10 GHz) | 0.0140 | 0.012 | 0.018 | 0.011 | 0.0144 | 0.0138 | 0.011 | 0.0086 | 0.0134 |
| Dk (40 GHz) | 3.0 | 3.0 | 3.1 | 3.0 | 3.0 | 3.0 | 2.9 | 3.0 | 2.6 |
| Df (40 GHz) | 0.0160 | 0.013 | 0.022 | 0.012 | 0.0156 | 0.0150 | 0.012 | 0.0093 | 0.0220 |
| Residual film ratio after | 72 | 81 | 69 | 81 | 83 | 84 | 85 | 77 | 97 |
| curing: RFA (%) | | | | | | | | | |
| Copper adhesion | B | B | C | B | C | D | C | B | D |
| Storage stability | B | A | C | B | A | A | C | B | C |
| RFA/tanδ40 | 45.0 | 62.3 | 31.4 | 67.5 | 53.2 | 56.2 | 70.8 | 83.1 | 44.1 |

As is apparent from Tables 1 to 10, in the Examples, by introducing a polyimide block structure at a specific ratio, it was possible to provide a photosensitive resin composition which has low dielectric properties, low cure shrinkage and satisfactory storage stability, and exhibits reduced phase separation during coating, and is capable of forming a cured relief pattern with high resolution and high copper adhesion. Meanwhile, in Comparative Examples 1 to 6 in which a polyimide structure is not included, the dielectric loss tangent was high and the residual film ratio after curing was low. In Comparative Example 7 in which polyimide was blended with a polyimide precursor having an imide group introduction ratio of 0, uniform coating could not be carried out because of poor compatibility, thus making it difficult to evaluate the resolution. It is considered that phase separation caused high dielectric loss tangent and low copper adhesion. In Comparative Example 8 in which a partially imidized polyimide precursor was used, the dielectric loss tangent was low, but it is considered that since it was difficult to control imidization, the coated film became white and cloudy, resulting in poor resolution. In Comparative Example 9 in which 100% imide polymer was used, a radically polymerizable monomer was required for patterning, and the residual film ratio after curing was high, but the dielectric loss tangent was high and the resolution was low. From the above results, sufficient results were not obtained in any of the Comparative Examples.

### INDUSTRIAL APPLICABILITY

The photosensitive resin composition of the present disclosure can be suitably used in the field of photosensitive materials which are useful for producing electric and electronic materials such as semiconductor devices and multilayer wiring boards.

1. A photosensitive resin composition comprising:
(A) 100 parts by weight of a copolymer resin containing a polyimide and polyimide precursor;
(B) 0.5 to 30 parts by weight of a photopolymerization initiator; and
(C) 100 to 1,000 parts by weight of a solvent;
wherein the copolymer resin containing the polyimide and polyimide precursor comprises a structure represented by the following general formula (1): 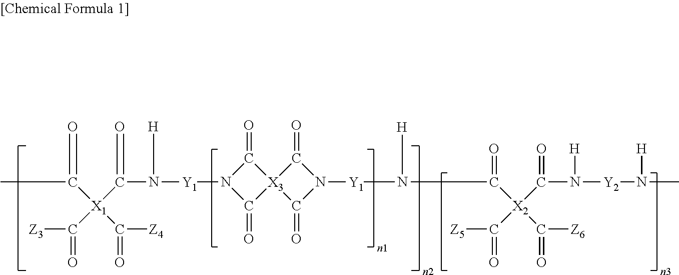
wherein, in formula (1), X₁, X₂ and X₃ are each independently a tetravalent organic group having 6 to 40 carbon atoms, Y₁ and Y₂ are each independently a divalent organic group having 6 to 40 carbon atoms, n₁ is an integer of 2 to 30, n₂ and n₃ are each independently an integer of 2 to 150, Z₃, Z₄, Zₛ and Z₆ are each independently a monovalent organic group, and at least one of Z₃, Z₄, Zₛ and Z₆ is a photopolymerizable functional group, and
the copolymer resin containing the polyimide and polyimide precursor satisfies 0.10<n₂/(n₂+n₃)<0.90.

2. The photosensitive resin composition according to claim 1, wherein the photopolymerizable functional group includes a structure represented by the following general formula (2): 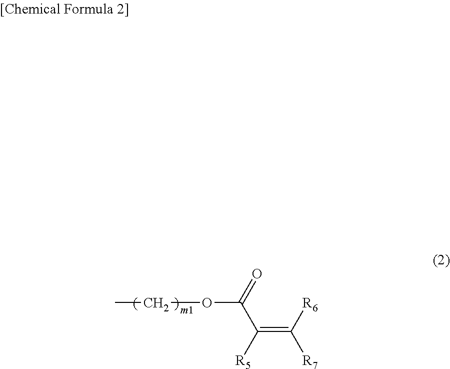
wherein, in formula (2), R₅, R₆ and R₇ are each independently a hydrogen atom or a monovalent organic group having 1 to 3 carbon atoms, and m₁ is an integer of 2 to 10.

3. The photosensitive resin composition according to claim 1, wherein n₂/(n₂+n₃) satisfies 0.40<n₂/(n₂+n₃)<0.90.

4. The photosensitive resin composition according to claim 1, wherein the copolymer resin containing the polyimide and polyimide precursor (A) does not contain a halogen atom.

5. The photosensitive resin composition according to claim 1, wherein, in polyimide of a polyimide cured film obtained by heating and curing the photosensitive resin composition at 350° C., the imide group concentration U, which is the ratio of the molecular weight of imide groups to the molecular weight of repeating units including structures derived from tetracarboxylic dianhydride and diamine, is 12% by weight to 26% by weight.

6. The photosensitive resin composition according to claim 1, wherein X₁, X₂ and X₃ of the copolymer resin containing the polyimide and polyimide precursor (A) include a structure represented by the following general formula (4): 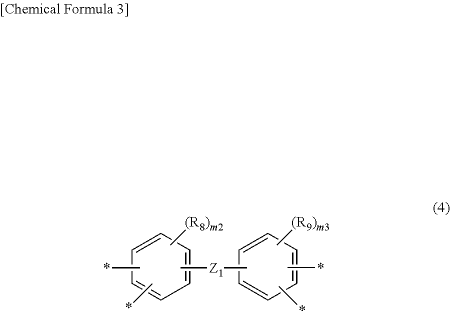
wherein, in formula (4), R₈ and R₉ are each independently an organic group having 1 to 10 carbon atoms, m₂ and m₃ are an integer selected from 0 to 4 and satisfy m₂+m₃>1, Z₁ is selected from the group consisting of a single bond, an organic group having 1 to 30 carbon atoms and an organic group containing a heteroatom, two of * mean bonding to the main chain of the resin, and the other two mean bonding to the side chain in the above general formula (1); and/or, Y₁ and/or Y₂ include(s) a structure represented by the following general formula (7): 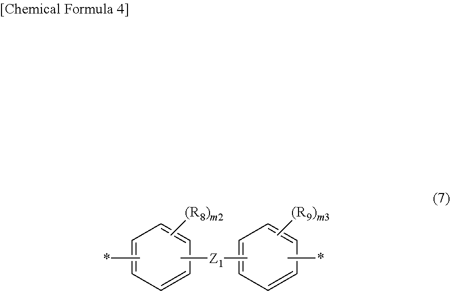
wherein, in formula (7), R₈ and R₉ are each independently an organic group having 1 to 10 carbon atoms, m₂ and m₃ are an integer selected from 0 to 4 and satisfy m₂+m₃>1, Z₁ is selected from the group consisting of a single bond, an organic group having 1 to 30 carbon atoms and an organic group containing a heteroatom, and * means bonding to the main chain of the resin.

7. The photosensitive resin composition according to claim 1, wherein the copolymer resin containing a polyimide and polyimide precursor (A) has reactive substituents which are polymerized by heat or light at the resin end, and are different from the photopolymerizable functional groups included in the repeating units.

8. The photosensitive resin composition according to claim 1, further comprising (D) a silane coupling agent.

9. The photosensitive resin composition according to claim 1, further comprising (E) a radically polymerizable compound.

10. The photosensitive resin composition according to claim 1, further comprising (F) a thermal crosslinking agent.

11. The photosensitive resin composition according to claim 1, further comprising (G) a filler.

12. A method for producing a polyimide cured film, the method comprising the following (1) to (5):
(1) applying the photosensitive resin composition according to claim 1 on a substrate to form a photosensitive resin layer on the substrate;
(2) heating and drying the photosensitive resin layer thus obtained;
(3) exposing the heat-dried photosensitive resin layer;
(4) developing the exposed photosensitive resin layer; and
(5) heat-treating the developed photosensitive resin layer to form a polyimide cured film.

13. A method for producing a polyimide cured film, the method comprising applying the resin composition according to claim 1 on a substrate, and subjecting the substrate to an exposure treatment, a development treatment and then a heat treatment, wherein the cured film has a dielectric loss tangent of 0.003 to 0.011 as measured at 40 GHz by the perturbation type split cylinder resonator method.

14. A polyimide cured film which has a dielectric loss tangent of 0.003 to 0.011 as measured at a frequency of 40 GHz by the perturbation type split cylinder resonator method, and has RFA of 0.81 to 0.93, and satisfies the following formula:
$$85 < RFA / tan {δ}_{40} < 175$$
wherein RFA represents a residual film ratio after heat curing (ratio), and tanδ₄₀ represents the dielectric loss tangent as measured at a frequency of 40 GHz by the perturbation type split cylinder resonator method.

15. A method for producing a copolymer containing a polyimide and polyimide precursor, the method comprising the following:
(i) subjecting a first tetracarboxylic dianhydride or an acid/substituent adduct thereof to a condensation reaction with a first diamine compound for imidization to obtain a diamine oligomer having a repeating unit of a polyimide structure;
(ii) subjecting the diamine oligomer to a condensation reaction with a second tetracarboxylic dianhydride or an acid/substituent adduct thereof to synthesize a polyimide-imide precursor moiety having a polyimide block moiety; and
(iii) subjecting the polyimide-imide precursor moiety to a condensation reaction with a third tetracarboxylic dianhydride or an acid/substituent adduct thereof and a second diamine compound to synthesize a polyimide precursor moiety, wherein the first tetracarboxylic dianhydride, the second tetracarboxylic dianhydride and the third tetracarboxylic dianhydride may be the same as or different from each other, at least one of the second tetracarboxylic dianhydride and the third tetracarboxylic dianhydride is in the form of an acid/substituent adduct having a photopolymerizable functional group, and the first diamine compound and the second diamine compound may be the same as or different from each other.

16. A method for producing a photosensitive resin composition, the method comprising:
producing a copolymer resin containing a polyimide and polyimide precursor by the method according to claim 15; and
mixing (A) 100 parts by weight of the copolymer resin containing the polyimide and polyimide precursor, (B) 0.5 to 30 parts by weight of a photopolymerization initiator, and (C) 100 to 1,000 parts by weight of a solvent to obtain a photosensitive resin composition.
